(19) United States
(12) Patent Application Publication
(10) Pub. No.: US 2015/0017457 A1
(43) Pub. Date: Jan. 15, 2015

(54) TRANSPARENT CONDUCTIVE FILM, CONDUCTIVE ELEMENT, COMPOSITION, INPUT DEVICE, DISPLAY DEVICE AND ELECTRONIC INSTRUMENT

(71) Applicant: DEXERIALS CORPORATION, Tokyo (JP)

(72) Inventors: Mikihisa Mizuno, Sendai-shi (JP); Naoto Kaneko, Sendai-shi (JP); Ryosuke Iwata, Utsunomiya-shi (JP); Yasuhisa Ishii, Utsunomiya-shi (JP)

(21) Appl. No.: 14/382,078

(22) PCT Filed: Mar. 5, 2013
(86) PCT No.: PCT/JP2013/055999

§ 371 Date: Aug. 29, 2014

(30) Foreign Application Priority Data
Mar. 6, 2012 (JP) 2012-049861

(51) Int. Cl. H01B 1/22; H05K 1/02; H05K 1/09; G06F 1/16; H05K 1/03

(52) U.S. Cl. CPC H01B 1/22; G06F 1/16; H05K 1/0306; H05K 1/09; H05K 1/0274; H05K 2201/0364
USPC 428/457; 252/514

(57) ABSTRACT

A transparent conductive film contains a metal filler, a colored compound adsorbed to the surface of the metal filler, and at least one of thiols, sulfides, and disulfides adsorbed to the surface of the metal filler. When the terminal on the metal filler side of the colored compound is not any of thiols, sulfides, and disulfides, at least one of colorless thiols, sulfides, and disulfides is adsorbed to the surface of the metal filler. According to this transparent conductive film, an increase in resistance can be suppressed while suppressing diffuse reflection of light on the surface of the metal filler.

### TECHNICAL FIELD

The present technique relates to a transparent conductive film, a conductive element, a composition, an input device, a display device, and an electronic instrument, and more particularly to a transparent conductive film including a metal filler.

### BACKGROUND ART

Metal oxides such as indium tin oxide (ITO) has been used in transparent conductive films in which light transmittance is required. Examples of such a transparent conductive film include a transparent conductive film provided on the display screen of a display panel, and furthermore a transparent conductive film of an information input device disposed on the display screen side of a display panel. However, the transparent conductive film in which a metal oxide is used has been formed by sputtering in a vacuum environment causing an increase in a manufacturing cost, and also has been subject to cracking and delamination caused by deformation such as bending and deflection.

Therefore, in place of the transparent conductive film in which a metal oxide is used, a transparent conductive film in which a metal wire is used has been considered. Such a transparent conductive film can be formed by coating and printing, and also has high resistance to bending and deflection. Transparent conductive films in which a metal wire is used have also attracted attention as next-generation transparent conductive films in which indium, being a rare metal, is not used (for example, see Patent Literatures 1 and 2, and Non-Patent Literature 1).

However, when the transparent conductive film in which a metal wire is used is provided on a display screen side of a display panel, diffuse reflection of outside light occurs on the surface of the metal wire, so that black display of the display panel slightly becomes bright, which is called a milky appearance. The milky appearance reduces contrast of the display content, and becomes a factor leading to deterioration in display properties.

Patent Literature 3 discloses a technique of performing metal plating treatment of a metal nanowire and then performing etching of the metal nanowire to form a metal nanotube (hollow nanostructure), so as to reduce diffuse reflection of light on the surface of the metal nanotube. Also, there is disclosed a technique of performing plating treatment of a metal nanowire and then oxidizing the metal nanowire thereby to darken or blacken the surface, so as to reduce diffuse reflection of light on the surface of the metal nanotube.

Patent Literature 2 proposes a technique of using a metal nanowire and a secondary conductive medium (for example, CNT (carbon nanotubes), conductive polymers, and ITO) in combination so as to prevent light scattering.

### CITATION LIST

### Patent Literature

Patent Literature 1: Japanese Translation of PCT Patent Application Publication No. 2010-507199
Patent Literature 2: Japanese Translation of PCT Patent Application Publication No. 2010-525526
Patent Literature 3: Japanese Translation of PCT Patent Application Publication No. 2010-525527

### Non-Patent Literature

Non-Patent Literature 1: “ACS Nano” 2010, VOL. 4, NO. 5, p. 2955-2963

### SUMMARY OF INVENTION

### Technical Problem

Therefore, an object of the present technique is to provide a transparent conductive film, a conductive element, a composition, an input device, a display device, and an electronic instrument each enabling prevention of diffuse reflection of light on the surface of a metal filler.

### Solution to Problem

In order to solve the aforementioned problems, a first technique is a transparent conductive film including:

a metal filler;

a colored compound provided on the surface of the metal filler; and

at least one of thiols, sulfides, and disulfides provided on the surface of the metal filler.

A second technique is a composition including:

a metal filler;

a colored compound provided on the surface of the metal filler; and

at least one of thiols, sulfides, and disulfides provided on the surface of the metal filler.

A third technique is a conductive element including:

a substrate; and

a transparent conductive film provided on the surface of the substrate,

wherein the transparent conductive film includes: a metal filler;

a colored compound provided on the surface of the metal filler; and

at least one of thiols, sulfides, and disulfides provided on the surface of the metal filler.

A fourth technique is an input device including:

a substrate; and

a transparent conductive film provided on the surface of the substrate,

wherein the transparent conductive film includes:

a metal filler;

a colored compound provided on the surface of the metal filler; and

at least one of thiols, sulfides, and disulfides provided on the surface of the metal filler.

A fifth technique is an input device including:

a first substrate, and a first transparent conductive film provided on the surface of the first substrate; and

a second substrate, and a second transparent conductive film provided on the surface of the second substrate,

wherein the first transparent conductive film and the second transparent conductive film each include:

a metal filler;

a colored compound provided on the surface of the metal filler; and

at least one of thiols, sulfides, and disulfides provided on the surface of the metal filler.

A sixth technique is an input device including:

a substrate having a first surface and a second surface;

a first transparent conductive film provided on the first surface; and

a second transparent conductive film provided on the second surface,

wherein the first transparent conductive film and the second transparent conductive film each include:

a metal filler;

a colored compound provided on the surface of the metal filler; and

at least one of thiols, sulfides, and disulfides provided on the surface of the metal filler.

A seventh technique is a display device including

a display unit, and an input device provided in the display unit or on the surface of the display unit,

wherein the input device includes a substrate, and a transparent conductive film provided on the surface of the substrate,

wherein the transparent conductive film includes:

a metal filler;

a colored compound provided on the surface of the metal filler; and

at least one of thiols, sulfides, and disulfides provided on the surface of the metal filler.

An eighth technique is an electronic instrument including

a display unit, and an input device provided in the display unit or on the surface of the display unit,

wherein the input device includes a substrate, and a transparent conductive film provided on the surface of the substrate,

wherein the transparent conductive film includes:

a metal filler;

a colored compound provided on the surface of the metal filler; and

at least one of thiols, sulfides, and disulfides provided on the surface of the metal filler.

According to the present technique, since the colored compound is provided on the surface of the metal filler, light incident on the surface of the metal filler can be absorbed by the colored compound. Thus, light reflection on the surface of the metal filler can be suppressed. Also, since at least one of thiols, sulfides, and disulfides is provided on the surface of the metal filler, an increase in resistance of the transparent conductive film can be suppressed.

### Advantageous Effects of Invention

As described above, according to the present technique, an increase in resistance of the transparent conductive film is suppressed while suppressing diffuse reflection of light on the surface of the metal filler.

### BRIEF DESCRIPTION OF DRAWINGS

FIG. 1 includes a cross-sectional view (A) illustrating an example of a configuration of a transparent conductive element according to a first embodiment of the present technique, and a schematic diagram (B) illustrating an enlarged surface of a metal filler contained in the transparent conductive film.

FIG. 2 includes cross-sectional views (A, B, and C) illustrating modifications of the transparent conductive element according to the first embodiment of the present technique.

FIG. 3 includes cross-sectional views (A, B, and C) illustrating modifications of the transparent conductive element according to the first embodiment of the present technique.

FIG. 4 includes cross-sectional views (A and B) illustrating modifications of the transparent conductive element according to the first embodiment of the present technique.

FIG. 5-1 includes a cross-sectional view (A) illustrating an example of a configuration of a transparent conductive element according to a second embodiment of the present technique, and cross-sectional views (B and C) illustrating modifications of the transparent conductive element according to the second embodiment of the present technique.

FIG. 5-2 is a manufacturing flow chart of the transparent conductive element according to the second embodiment of the present technique.

FIG. 5-3 is a manufacturing flow chart of a transparent conductive element according to a modification of the second embodiment of the present technique.

FIG. 5-4 is a manufacturing flow chart of a transparent conductive element according to a modification of the second embodiment of the present technique.

FIG. 6 includes schematic diagrams (A, B, and C) for describing an example of a surface modification process with a colored compound and a surface protective agent.

FIG. 7 includes a cross-sectional view (A) illustrating an example of a configuration of an information input device according to a fifth embodiment of the present technique, and a perspective view (B) illustrating an example of a configuration of the information input device according to the fifth embodiment of the present technique.

FIG. 8 includes cross-sectional view (A and B) illustrating modifications of the information input device according to the fifth embodiment of the present technique.

FIG. 9 includes cross-sectional view (A and B) illustrating modifications of the information input device according to the fifth embodiment of the present technique.

FIG. 10 is a cross-sectional view illustrating an example of a configuration of a display device according to a sixth embodiment of the present technique.

FIG. 11 is a perspective view illustrating an appearance of a television set according to a seventh embodiment of the present technique.

FIG. 12 includes perspective views (A and B) illustrating an appearance of a digital camera according to the seventh embodiment of the present technique.

FIG. 13 is a perspective view illustrating an appearance of a notebook personal computer according to the seventh embodiment of the present technique.

FIG. 14 is a perspective view illustrating an appearance of a video camera including the display unit according to the seventh embodiment of the present technique.

FIG. 15 is a front view illustrating an appearance of a mobile terminal device including the display unit according to the seventh embodiment of the present technique.

FIG. 16 is a plan view of a photomask used in Example 10.

FIG. 17-1 is an optical micrograph (at 100×) of Example 10.

FIG. 17-2 is an optical micrograph (at 500×) of Example 10.

### DESCRIPTION OF EMBODIMENTS

### Summary

The present inventors have made extensive studies for solving the above-described problem. The summary thereof will be described below. As described above, transparent conductive films including a metal filler have problems in which outside light is diffusely reflected on the surface of the metal filler. To address this concern, the present inventors have made intensive studies for solving this problem. As a result, they have found a technique of providing a colored compound on the surface of the metal filler.

However, as a result of further intensive studies on this technique by the present inventors, it has been understood that although this technique enables suppression of diffuse reflection of outside light on the surface of the metal nanowire, the resistance if the transparent conductive film increases. To address this concern, the inventors have made intensive studies for alleviating this problem. As a result, the inventors have found a technique of providing at least one of thiols and sulfides on the surface of the metal filler to thereby suppress the increase in resistance of the transparent conductive film caused by the colored compound.

### EMBODIMENTS

Embodiments of the present technique will be described in the following order with reference to the drawings.

1. First embodiment (Example of configuration of transparent conductive element)
2. Second embodiment (Example of configuration of transparent conductive element having patterned transparent conductive film)
3. Third embodiment (Manufacturing method of transparent conductive film, including film formation of dispersion containing metal filler followed by adsorption treatment of colored compound)
4. Fourth embodiment (Manufacturing method of transparent conductive film, including adsorption of colored compound to surface of metal filler followed by film formation of dispersion containing the metal filler)
5. Fifth embodiment (Example of configuration of information input device and display device)
6. Sixth embodiment (Example of configuration of a display device)
7. Seventh embodiment (Example of configuration of electronic instrument)

### 1. First Embodiment

### Configuration of Transparent Conductive Element

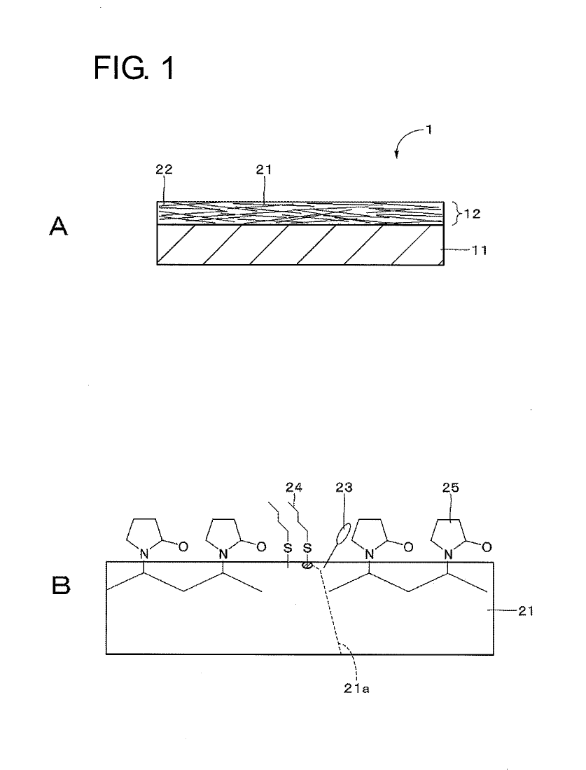

The cross-sectional view A of FIG. 1 illustrates an example of a configuration of a transparent conductive element according to a first embodiment of the present technique. A transparent conductive element 1 includes a substrate 11 and a transparent conductive film 12 provided on the surface of the substrate 11.

### (Substrate)

The substrate 11 is, for example, a transparent inorganic substrate or a transparent plastic substrate. The substrate 11 may have a shape of, for example, film, sheet, plate, and block. Examples of the material of the inorganic substrate may include quartz, sapphire, and glass. Examples of the material of the plastic substrate may include known polymer materials. Specific examples of the known polymer materials may include triacetyl cellulose (TAC), polyester (TPEE), polyethylene terephthalate (PET), polyethylene naphthalate (PEN), polyimide (PI), polyamide (PA), aramid, polyethylene (PE), polyacrylate, polyethersulfone, polysulfone, polypropylene (PP), diacetyl cellulose, polyvinyl chloride, acrylic resin (PMMA), polycarbonate (PC), epoxy resin, urea resin, urethane resin, melamine resin, and cycloolefin polymer (COP). When the plastic material is used as the substrate 11, the thickness of the substrate 11 is preferably, but not limited to, 5 to 500 μm from the viewpoint of productivity.

### (Transparent Conductive Film)

The reflection L value (that is, the L value in the L*a*b* color system calculated from measurement of a spectral reflectivity) of the transparent conductive film 12 is preferably 8.5 or less, and more preferably 8 or less. This is because the milky appearance can be alleviated, and the transparent conductive film 12 and the transparent conductive element 1 can be suitably allowed to be disposed on the display screen side of a display device. Here, the reflection L value can be controlled by the amount of a colored compound adsorbed to a metal filler 21.

The transparent conductive film 12 includes the metal filler 21, a resin material 22, and a colored compound that modifies the surface of the metal filler 21. The transparent conductive film 12 further includes at least one of thiols and sulfides that modifies the surface of the metal filler 21. Hereinafter, at least one of thiols, sulfides, and disulfides that modifies the surface of the metal filler 21 is also referred to as a surface protective agent. The transparent conductive film 12 may further include, as necessary, additives such as a dispersant, a thickener, and a surfactant as a component other than the above-described components.

The schematic diagram B of FIG. 1 illustrates an enlarged surface of the metal filler 21 contained in the transparent conductive film 12. The surface of the metal filler 21 is modified with a colored compound 23, and a colorless surface protective agent 24 that is at least one of thiols, sulfides, and disulfides. In the transparent conductive element 1 in the schematic diagram B of FIG. 1, the surface of the metal filler 21 is also modified with a dispersant 25.

Modifying the surface of the metal filler 21 with the colored compound 23 causes light incident on the surface of the metal filler to be absorbed by the colored compound 23. Thus, diffuse reflection of light on the surface of the metal filler 21 can be suppressed.

Modifying the surface of the metal filler 21 with the surface protective agent 24 that is at least one of thiols, sulfides, and disulfides enables suppression of the increase in resistance of the transparent conductive film 12 caused by modification of the surface of the metal filler 21 with the colored compound 23.

It is preferred that the surface protective agent 24 that is at least one of thiols, sulfides, and disulfides modify an unstable portion such as a crystal grain boundary 21a, a portion not protected by the dispersant 25 (a portion where the metal surface is exposed), and the like, on the surface of the metal filler 21.

The dispersant 25 that modifies the surface of the metal filler 21 is added and adsorbed to the metal filler 21 to suppress the aggregation of the metal fillers 21 in a dispersion forming the transparent conductive film 12 and to improve the dispersibility of the metal filler 21 in the transparent conductive film 12. The dispersion containing the metal filler 21 will be described in detail below.

### (Metal Filler)

The main component of the metal filler 21 is a metal material. As the metal material, for example, at least one selected from the group consisting of Ag, Au, Ni, Cu, Pd, Pt, Rh, Ir, Ru, Os, Fe, Co and Sn may be used.

Examples of the shape of the metal filler 21 may include, but are not particularly limited to, a spherical shape, an ellipsoid shape, a needle shape, a plate shape, a flake shape, a tubular shape, a fiber shape, a bar shape (rod shape), and indefinite shapes. Here, the fiber shape includes a case in which the metal filler 21 is formed with a composite material. The fiber shape also includes a wire shape. Hereinafter, a wire-shaped metal filler is referred to as a “metal wire.” Here, two or more of the metal filler 21 with the above-described shapes may be combined to be used. Here, the spherical shape includes not only an exact spherical shape, but also nearly spherical shapes in which the exact spherical shape is slightly flattened or distorted. The ellipsoid shape includes not only a strictly ellipsoid shape, but also nearly ellipsoid shapes in which the strictly ellipsoid shape is slightly flattened or distorted.

The metal filler 21 is, for example, a fine metal nanowire having a diameter of nm order. For example, when the metal filler 21 is a metal wire, it is preferred that the metal wire have an average minor axis diameter (an average diameter of wires) of larger than 1 nm and not larger than 500 nm, and an average major axis diameter of larger than 1 μm and not larger than 1000 The average major axis diameter of the metal wire is more preferably 5 μm or more and 50 μm or less. When the average minor axis diameter is 1 nm or less, the conductivity of the metal wire deteriorates, thereby inhibiting the metal wire from functioning as a conductive film after coating. On the other hand, when the average minor axis diameter is more than 500 nm, the total light transmittance of the transparent conductive film 12 deteriorates. When the average major axis diameter is 1 μm or less, the metal wires are unlikely to be linked to each other, and the transparent conductive film 12 is unlikely to function as a conductive film. On the other hand, when the average major axis diameter is longer than 1000 μm, the total light transmittance of the transparent conductive film 12 tends to deteriorate, and the dispersibility of the metal wires in the dispersion used for forming the transparent conductive film 12 tends to deteriorate. When the average major axis diameter of the metal wire is 5 μm or more and 50 μm or less, the conductivity of the transparent conductive film 12 can be improved, and occurrence of a short circuit when the transparent conductive film 12 is patterned can decrease. On the other hand, the metal filler 21 may have a wire shape in which metal nanoparticles are linked to each other in a beaded manner. In this case, the length is not limited.

The basis weight of the metal fillers 21 is preferably 0.001 to 1.000 [g/m²]. When the basis weight is less than 0.001 [g/m²], the metal fillers 21 are not sufficiently present in the transparent conductive film 12, and the conductivity of the transparent conductive film 12 deteriorates. On the other hand, the higher basis weight of the metal fillers 21 decreases the sheet resistance value. However, when the basis weight is more than 1.000 [g/m²], the total light transmittance of the transparent conductive film 12 deteriorates.

### (Resin Material)

The resin material 22 is a so-called binder material, and in the transparent conductive film 12, the metal fillers 21 are dispersed in the cured resin material 22. The resin material 22 used herein can be widely selected from known transparent naturally-occurring polymer resins and synthetic polymer resins, and may be a thermoplastic resin, a thermosetting resin, or a photocurable resin. Examples of the thermoplastic resin may include polyvinyl chloride, a vinyl chloride-vinyl acetate copolymer, polymethyl methacrylate, cellulose nitrate, chlorinated polyethylene, chlorinated polypropylene, vinylidene fluoride, ethyl cellulose, and hydroxypropyl methylcellulose. Examples of the thermo(photo) setting resin which is cured by heat, light, electron beams, and radioactive rays may include melamine acrylate, urethane acrylate, isocyanate, epoxy resins, polyimide resins, and silicon resins such as acrylic-modified silicate.

Also, photosensitive resins may be used as the resin material 22. Photosensitive resins are resins that are chemically changed by irradiation of light beams, electron beams or radiation so that the solubility to a solvent is changed. The photosensitive resins may be either a positive-type (an exposed portion is dissolved in a developer) or a negative-type (an exposed portion becomes undissolved in a developer). By using the photosensitive resins as the resin material 22, the number of steps when patterning the transparent conductive film 22 by etching can be reduced as described later.

As the positive photosensitive resin, known positive-type photoresist materials can be used. Examples thereof may include a composition in which a naphthoquinone diazide compound and a polymer (such as novolac resins, acrylic copolymer resins, and hydroxypolyamide) are combined. As the negative photosensitive material, known negative photoresist materials can be used. Examples thereof may include: a composition in which a crosslinking agent (such as bisazide compounds, hexamethoxy methyl melamine, and tetramethoxy glycouril) and a polymer (such as polyvinyl alcohol-based polymer, polyvinyl butyral-based polymer, polyvinyl pyrrolidone-based polymer, polyacrylamide-based polymer, polyvinyl acetate-based polymer, and polyoxyalkylene-based polymer) are combined; a polymer (polyvinyl alcohol-based polymer, polyvinyl butyral-based polymer, polyvinyl pyrrolidone-based polymer, polyacrylamide-based polymer, polyvinyl acetate-based polymer, and polyoxyalkylene-based polymer) to which a photosensitive group (such as an azide group, a phenyl azide group, a quinone azide group, a stilbene group, a chalcone group, a diazonium salt group, a cinnamic acid group, and an acrylic acid group) is introduced; and a composition in which a photopolymerization initiator and at least one of a (meth)acrylic monomer and a (meth)acrylic oligomer are combined. An example of a commercially available product may include BIOSURFINE-AWP manufactured by Toyo Gosei Co., Ltd. as a polymer to which a photosensitive group is introduced.

Also, a surfactant, a viscosity modifier, a dispersant, a cure promoting catalyst, and a plasticizer, as well as a stabilizer such as an antioxidant and an anti-sulfurizing agent may be added as additives to the resin material 22 as necessary.

### (Surface Protective Agent)

In the transparent conductive film 12, at least one of thiols, sulfides, and disulfides that are the surface protective agent 24 is adsorbed to the surface of the metal filler 21. Here, adsorption means a phenomenon of existing on the surface of the metal filler 21, or on and near the surface of the metal filler 21. While the adsorption may be either chemical adsorption or physical adsorption, chemical adsorption is preferred in terms of having higher adsorbability. Also, a surface protective agent 24 that is chemically adsorbed and a surface protective agent 24 that is physically adsorbed may coexist. Here, the chemical adsorption means the adsorption that occurs between the surface of the metal filler and the thiols associated with a chemical bond such as a covalent bond, an ionic bond, a coordinate bond, and a hydrogen bond. The physical adsorption occurs due to van der Waals force. The adsorption may be electrostatic.

The thiols, sulfides, and disulfides that function as the surface protective agent 24 may be colored or colorless, or a combination thereof for use. In the present invention, however, the colored thiols, sulfides, and disulfides which are adsorbed to the metal filler 21 are classified in the category of the colored compound 23 constituting the transparent conductive film according to the present invention. Also, in the present invention, when the terminal on the metal filler side of the colored compound 23 is thiols, sulfides, or disulfides, thiols, sulfides, or disulfides do not need to be adsorbed to the surface of the metal filler 21 in addition to the colored compound 23. Therefore, when the terminal on the metal filler side of the colored compound 23 is thiols, sulfides, or disulfides, the colored compound 23 provided on the surface of the metal filler 21 and the thiols, sulfides, or disulfides provided as the surface protective agent 24 on the surface of the metal filler can be shared with each other.

On the other hand, when the terminal on the metal filler side of the colored compound 23 is not any of thiols, sulfides, and disulfides, at least one of colorless thiols, sulfides, and disulfides is adsorbed as the surface protective agent 24 to the surface of the metal filler 21.

### (Thiols)

The colorless thiols functioning as the surface protective agent 24 contain, for example, at least a thiol group, and a linear, branched or cyclic hydrocarbon group. Two or more thiol groups may be contained. The hydrocarbon group may be saturated or unsaturated. Some of hydrogen atoms in the hydrocarbon group may be substituted with a hydroxyl group, an amino group, a carboxyl group, a halogen atom, an alkoxysilyl group and the like.

More specifically, examples of the colorless thiols may include 1-propanethiol, 3-mercaptopropionic acid, (3-mercaptopropyl)trimethoxysilane, 1-butanethiol, 2-butanethiol, isobutyl mercaptan, isoamyl mercaptan, cyclopentanethiol, 1-hexanethiol, cyclohexanethiol, 6-hydroxy-1-hexanethiol, 6-amino-1-hexanethiol hydrochloride, 1-heptanethiol, 7-carboxy-1-heptanethiol, 7-amide-1-heptanethiol, 1-octanethiol, tert-octanethiol, 8-hydroxy-1-octanethiol, 8-amino-1-octanethiol hydrochloride, 1H,1H,2H,2H-perfluorooctanethiol, 1-nonanethiol, 1-decanethiol, 10-carboxy-1-decanethiol, 10-amide-1-decanethiol, 1-naphthalenethiol, 2-naphthalenethiol, 1-undecanethiol, 11-amino-1-undecanethiol hydrochloride, 11-hydroxy-1-undecanethiol, 1-dodecanethiol, 1-tetradecanethiol, 1-hexadecanethiol, 16-hydroxy-1-hexadecanethiol, 16-amino-1-hexadecanethiol hydrochloride, 1-octadecanethiol, 1,4-butanedithiol, 2,3-butanedithiol, 1,6-hexanedithiol, 1,2-benzenedithiol, 1,9-nonanedithiol, 1,10-decanedithiol, and 1,3,5-benzenetrithiol. These thiols may be used either singly or in any combination thereof.

### (Sulfides)

The colorless sulfides functioning as the surface protective agent 24 contain, for example, at least a sulfide group, and a linear, branched or cyclic hydrocarbon group. Two or more sulfide groups may be contained. Some of hydrogen atoms in the hydrocarbon group may be substituted with a hydroxyl group, an amino group, a carboxyl group, a halogen atom, an alkoxysilyl group and the like.

More specifically, examples of the colorless sulfides may include propyl sulfide, furfuryl sulfide, hexyl sulfide, phenyl sulfide, phenyl trifluoromethyl sulfide, bis(4-hydroxyphenyl) sulfide, heptyl sulfide, octyl sulfide, nonyl sulfide, decyl sulfide, dodecyl methyl sulfide, dodecyl sulfide, tetradecyl sulfide, hexadecyl sulfide, and octadecyl sulfide. These sulfides may be used either singly or in any combination thereof.

### (Disulfides)

Examples of the colorless disulfides functioning as the surface protective agent 24 may include 2-hydroxyethyl disulfide, propyl disulfide, isopropyl disulfide, 3-carboxypropyl disulfide, allyl disulfide, isobutyl disulfide, tert-butyl disulfide, amyl disulfide, isoamyl disulfide, 5-carboxypentyl disulfide, furfuryl disulfide, hexyl disulfide, cyclohexyl disulfide, phenyl disulfide, 4-aminophenyl disulfide, heptyl disulfide, 7-carboxyheptyl disulfide, benzyl disulfide, tert-octyl disulfide, decyl disulfide, 10-carboxydecyl disulfide, and hexadecyl disulfide.

### (Colored Compound)

In the transparent conductive film 12, the colored compound 23 is adsorbed to the surface of the metal filler 21. Here, adsorption means, as described earlier, a phenomenon of existing on the surface of the metal filler 21, or on and near the surface of the metal filler 21.

The colored compound 23 preferably covers the surface of the metal filler 21 as a monomolecular film. This can suppress the reduction in transparency to visible light. In addition, the amount of the colored compound 23 to be used can be minimized.

Preferably, the colored compounds 23 are distributed only on the surface of the metal filler 21. This can suppress the reduction in transparency to visible light. In addition, the amount of the colored compound 23 to be used can be minimized.

The colored compound 23 has the absorbing power of absorbing light in the visible light range. Here, the visible light range is a wavelength range approximately 360 nm or more and 830 nm or less.

The colored compound 23 has, for example, a chromophore R having absorption in the visible light range, and a functional group X being adsorbed to the metal filler 21. The colored compound 23 has, for example, a structure represented by the general formula [R-X]. Here, the structure of the colored compound 23 is not limited to the structure represented by this general formula. For example, the number of the functional groups X is not limited to one, and can be two or more.

Among these, the chromophore [R] is, for example, at least one selected from the group consisting of an unsaturated alkyl group, an aromatic ring, a heterocycle, and a metal complex. Specific examples of such a chromophore [R] may include naphthoquinone derivatives, stilbene derivatives, indophenol derivatives, diphenylmethane derivatives, anthraquinone derivatives, triarylmethane derivatives, diazine derivatives, indigoid derivatives, xanthene derivatives, oxazine derivatives, phthalocyanine derivatives, acridine derivatives, and sulfur atom-containing compounds such as thiazine derivatives. These can have a nitroso group, a nitro group, an azo group, a methine group, an amino group, a ketone group, a thiazolyl group, and the like. Also, the chromophore [R] may contain a metal ion. From the viewpoint of improving the transparency of the transparent conductive film 12, as the chromophore [R], at least one selected from a compound having a color developing structure such as cyanine, quinone, ferrocene, triphenylmethane, and quinoline, a Cr complex, a Cu complex, an azo group-containing compound, and an indoline group-containing compound is also preferably used.

Examples of the functional group which bonds to a metal constituting the metal filler 21 include a sulfo group (including sulfonate), a sulfonyl group, a sulfonamide group, a carboxylic acid group (including carboxylate), an amino group, an amide group, a phosphate group (including phosphoric acid salt and phosphoric acid ester), a phosphino group, a silanol group, an epoxy group, an isocyanate group, a cyano group, a vinyl group, a carbinol group, a hydroxyl group, a thiol group, a sulfide group, a disulfide group and a disulfide group. The functional group [X] of the colored compound 23 when at least one of the thiols, sulfides, and disulfides is used as the colorless surface protective agent 24 is preferably a carboxylic acid group, a phosphate group, a sulfo group, a hydroxyl group and the like, and more preferably a carboxylic acid group.

Here, when the functional group [X] has N (nitrogen), S (sulfur), or O (oxygen) which can be coordinated to a metal constituting the metal filler 21, in the case of these atoms, the functional group [X] may constitute part of the chromophore [R], so that the colored compound 23 becomes a compound having a heterocyclic ring.

Examples of the above-described colored compound 23 may include dyes such as acidic dyes and direct dyes. Examples of more specific dyes may include dyes having a sulfo group such as Kayakalan Bordeaux BL, Kayakalan Brown GL, Kayakalan Gray BL167, Kayakalan Yellow GL143, Kayakalan Black 2RL, Kayakalan Black BGL, Kayakalan Orange RL, Kayarus Cupro Green G, Kayarus Supra Blue MRG, and Kayarus Supra Scarlet BNL200 manufactured by Nippon Kayaku Co., Ltd.; and Lanyl Olive BG manufactured by Taoka Chemical Company, Limited. Other examples thereof may include Kayalon Polyester Blue 2R-SF, Kayalon Microester Red AQ-LE, Kayalon Polyester Black ECX300, and Kayalon Microester Blue AQ-LE manufactured by Nippon Kayaku Co., Ltd. Also, examples of dyes having a carboxyl group may include dyes for a dye-sensitized solar cell. Examples thereof may include, as a Ru complex, N3, N621, N712, N719, N749, N773, N790, N820, N823, N845, N886, N945, K9, K19, K23, K27, K29, K51, K60, K66, K69, K73, K77, Z235, Z316, 2907, Z907Na, 2910, 2991, CYC-B1 and HRS-1; and, as an organic pigment type, Anthocyanine, WMC234, WMC236, WMC239, WMC273, PPDCA, PTCA, BBAPDC, NKX-2311, NKX-2510, NKX-2553 (manufactured by Hayashibara Co., Ltd.), NKX-2554 (manufactured by Hayashibara Co., Ltd.), NKX-2569, NKX-2586, NKX-2587 (manufactured by Hayashibara Co., Ltd.), NKX-2677 (manufactured by Hayashibara Co., Ltd.), NKX-2697, NKX-2753, NKX-2883, NK-5958 (manufactured by Hayashibara Co., Ltd.), NK-2684 (manufactured by Hayashibara Co., Ltd.), Eosin Y, Mercurochrome, MK-2 (manufactured by Soken Chemical & Engineering Co., Ltd.), D77, D102 (manufactured by Mitsubishi Paper Mills, Ltd.), D120, D131 (manufactured by Mitsubishi Paper Mills, Ltd.), D149 (manufactured by Mitsubishi Paper Mills, Ltd.), D150, D190, D205 (manufactured by Mitsubishi Paper Mills, Ltd.), D358 (manufactured by Mitsubishi Paper Mills, Ltd.), JK-1, JK-2, JK-5, ZnTPP, H2TC1PP, H2TC4PP, phthalocyanine dye (zinc phtalocyanine-2,9,16,23-tetra-carboxylic acid), 2-[2′-(zinc9′,16′,23′-tri-tert-butyl-29H,31H-phthalocyanyl)] succinic acid, polythiohene dye (TT-1), pendant type polymer, and cyanine dye (P3TTA, Cl-D, SQ-3, B1).

Also, as the colored compound 23, colored compounds used as a pigment can be used. Examples thereof may include Opera Red, Permanent Scarlet, Carmine, Violet, Lemon Yellow, Permanent Yellow Deep, Sky Blue, Permanent Green Light, Permanent Green Middle, Burnt Sienna, Yellow Ocher, Permanent Orange, Permanent Lemon, Permanent Red, Viridian (Hue), Cobalt Blue (Hue), Prussian Blue (Hue), Jet Black, Permanent Scarlet, and Violet manufactured by Turner Color Works LTD.

Other examples thereof may include Bright Red, Cobalt Blue Hue, Ivory Black, Yellow Ochre, Permanent Green Light, Permanent Yellow Light, Burnt Sienna, Ultramarine Deep, Vermilion Hue and Permanent Green as a colored compound manufactured by Holbein Works Ltd. Among these colored compounds, Permanent Scarlet, Violet, and Jet Black (manufactured by Turner Color Works LTD.) are preferred.

Furthermore, as the colored compound 23, food colored compounds can also be used. Examples thereof may include Food Red No. 2 Amaranth, Food Red No. 3 Erythrosine, Food Red No. 102 New Coccine, Food Red No. 104 Phloxine, Food Red No. 105 Rose Bengal, Food Red No. 106 Acid Red, Food Blue No. 1 Brilliant Blue, Food Red No. 40 Allura Red, Food Blue No. 2 Indigo Carmine, Red No. 226 Helindone Pink CN, Red No. 227 Fast Acid Magenta, Red No. 230 Eosine YS, Green No. 204 Pyranine Conc., Orange No. 205 Orange II, Blue No. 205 Alphazurine, Purple No. 401 Alizurol Purple, and Black No. 401 Naphthol Blue Black, which are manufactured by Daiwa Dyestuff Mfg. Co., Ltd. Naturally-occurring colored compounds can be also used. Examples thereof may include Hi Red G-150 (water soluble, grape skin dye), Cochineal Red AL (water soluble, cochineal dye), Hi Red MC (water soluble, cochineal dye), Hi Red BL (water soluble, beet red), Daiwamonas LA-R (water soluble, monascus dye), Hi Red V80 (water soluble, purple sweet potato dye), Annatto N2R-25 (water dispersible, annatto dye), Annatto WA-20 (water soluble annatto, annatto dye), Hi Orange SS-44R (water dispersible, low viscosity, paprika dye), Hi Orange LH (oil soluble, paprika dye), Hi Green B (water soluble, green coloring agent), Hi Green F (water soluble, green coloring agent), Hi Blue AT (water soluble, gardenia blue dye), Hi Melon P-2 (water soluble, green coloring agent), Hi Orange WA-30 (water dispersible, paprika dye), Hi Red RA-200 (water soluble, red radish dye), Hi Red CR-N (water soluble, red cabbage color), Hi Red EL (water soluble, elderberry dye), and Hi Orange SPN (water dispersible, paprika dye), which are produced by Daiwa Dyestuff Mfg. Co., Ltd.

As the colored compound 23 to be used, for each metal constituting the metal filler 21, a compound which can be adsorbed to the metal and can be dissolved in the solvent used in a manufacturing process of the transparent conductive film 12 at a predetermined concentration is preferably selected from the compounds represented by the above-mentioned formula [R-X].

Whether or not the surface of the metal filler 21 is modified with the colored compound 23 can be checked as below. First, the transparent conductive film 12 containing the metal filler 21 to be checked is immersed in a solution capable of etching a known metal for approximately several to a dozen hours. Then, the metal filler 21 and the modifying compound with which the surface of the metal filler 21 is modified are extracted. Next, a solvent used is removed from the extracted liquid by heating or reduced pressure, to thereby concentrate the extracted components. At this time, separation by chromatography may be performed as necessary. Next, a gas chromatograph (GC) analysis of the above-mentioned concentrated extracted components is performed to check molecules of the modifying compounds and fragments thereof, thereby enabling judgment on whether or not the modifying compound is present. Also, by using a deuterated solvent for extraction of the modifying compounds, the modifying compounds or fragments thereof can be identified by an NMR analysis.

### (Dispersant)

In the transparent conductive film 12 illustrated in FIG. 1, the dispersant 25, for example, is adsorbed to the surface of the metal filler 21. Here, adsorption means, as described earlier, a phenomenon of existing on the surface of the metal filler 21, or on and near the surface of the metal filler 21.

Examples of the dispersant 25 to be used may include polyvinylpyrrolidone (PVP), and amino group-containing compounds such as polyethylenimine. Other examples thereof may include compounds containing a functional group such as a sulfo group (including sulfonate), a sulfonyl group, a sulfonamide group, a carboxylic acid group (including carboxylate), an amide group, a phosphate group (including phosphoric acid salt and phosphoric acid ester), a phosphino group, a silanol group, an epoxy group, an isocyanate group, a cyano group, a vinyl group, a thiol group, and a carbinol group, wherein the compound is adsorbed to metal to improve the dispersibility of the metal fillers 21 in a solvent. These dispersants may be used either singly or in any combination thereof. The dispersant 25 is preferably adsorbed to the metal filler 21 in such an amount that the conductivity of the transparent conductive film 12 does not deteriorate.

### [Effects]

As described above, according to the first embodiment, since the colored compound 23 is caused to be adsorbed to the surface of the metal filler, diffuse reflection of light on the surface of the metal filler can be suppressed.

The colored compound 23 has a function of absorbing the light which have been scattered on the surface of the metal filler causing the milky appearance. In the conventional transparent conductive film, the light which has caused the milky appearance is basically light that hardly transmits through the transparent conductive film. Therefore, even when the surface of the metal filler is modified with the colored compound 23, a decrease in transparency is suppressed.

### <Modifications>

### (First Modification)

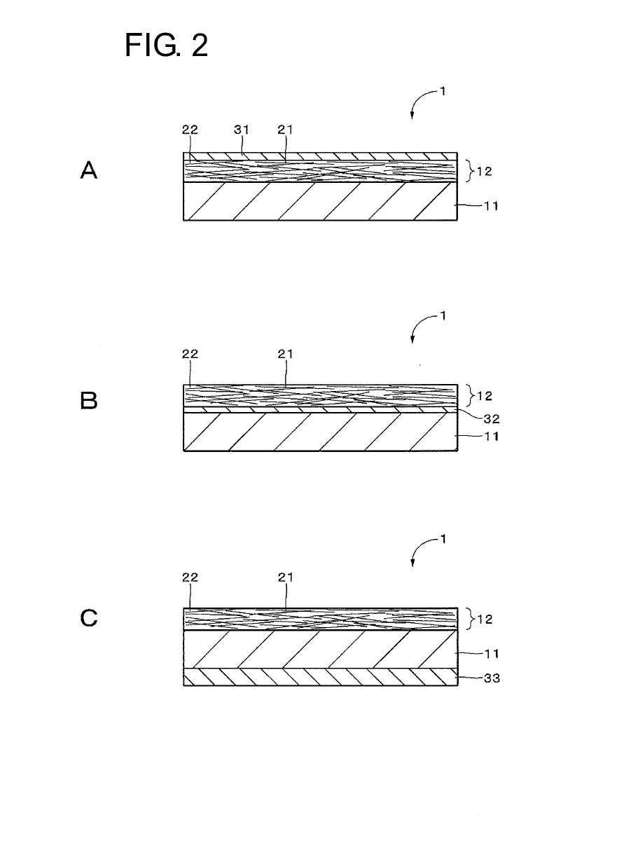

As illustrated in the cross-sectional view A of FIG. 2, the transparent conductive element 1 may further include an overcoat layer 31 on the surface of the transparent conductive film 12. The overcoat layer 31 is provided for protecting the transparent conductive film 12 including the metal filler 21. The overcoat layer 31 has optical transparency to visible light. The overcoat layer 31 is, for example, composed of a polyacryl-based resin, a polyamide-based resin, a polyester-based resin, or a cellulose-based resin, or composed of a hydrolysis product or a dehydration-condensation product of a metal alkoxide. Also, such an overcoat layer 31 preferably has a thickness that does not inhibit optical transparency to visible light. The overcoat layer 31 may have at least one function selected from the function group consisting of a hard coat function, an anti-glare function, an anti-reflection function, an anti-Newton ring function, and an anti-blocking function.

### (Second Modification)

As illustrated in the cross-sectional view B of FIG. 2, the transparent conductive element 1 may further include an anchor layer 32 between the substrate 11 and the transparent conductive film 12. The anchor layer 32 is provided for improving adhesion between the substrate 11 and the transparent conductive film 12.

The anchor layer 32 has optical transparency to visible light. The anchor layer 32 is composed of a polyacryl-based resin, a polyamide-based resin, a polyester-based resin, or a cellulose-based resin, or composed of a hydrolysis product or a dehydration condensation product of a metal alkoxide. The anchor layer 32 preferably has a thickness that does not inhibit optical transparency to visible light.

### (Third Modification)

As illustrated in the cross-sectional view C of FIG. 2, the transparent conductive element 1 may further include a hard coat layer 33 on the surface of the substrate 11. The hard coat layer 33 is provided on one main surface of the substrate 11 which is on the opposite side to the other main surface on which the transparent conductive film 12 is provided. The hard coat layer 33 is provided for protecting the substrate 11.

The hard coat layer 33 preferably has optical transparency to visible light, and is composed of an organic hard coat agent, an inorganic hard coat agent, an organic-inorganic hard coat agent, and the like. The hard coat layer 33 preferably has a thickness that does not inhibit optical transparency to visible light.

### (Fourth Modification)

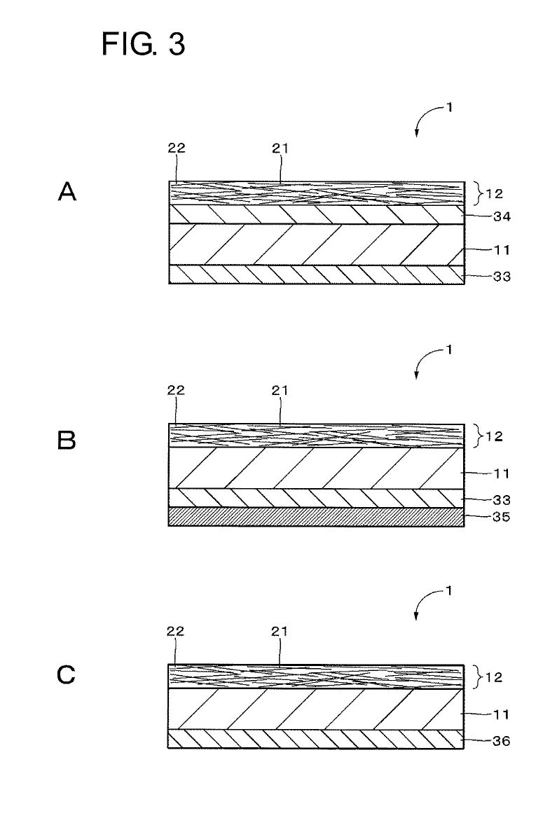

As illustrated in the cross-sectional view A of FIG. 3, the transparent conductive element 1 may further include hard coat layers 33 and 34 on respective surfaces of the substrate 11. The hard coat layer 34 is provided on one main surface of the substrate 11 which is on the side on which the transparent conductive film 12 is provided. On the other hand, the hard coat layer 33 is provided on one main surface of the substrate 11 which is on the opposite side to the main surface on which the transparent conductive film 12 is provided. The hard coat layers 33 and 34 are provided for protecting the substrate 11.

The hard coat layers 33 and 34 preferably have optical transparency to visible light, and are composed of an organic hard coat agent, an inorganic hard coat agent, an organic-inorganic hard coat agent, and the like. The hard coat layers 33 and 34 preferably have a thickness that does not inhibit optical transparency to visible light.

### (Fifth Modification)

As illustrated in the cross-sectional view B of FIG. 3, the transparent conductive element 1 may further include a hard coat layer 33 provided on the surface of the substrate 11, and an anti-reflection layer 35 provided on the surface of the hard coat layer 33. The hard coat layer 33 and the anti-reflection layer 35 are provided on one main surface of the substrate 11 which is on the opposite side to the main surface on which the transparent conductive film 12 is provided. Examples of the anti-reflection layer 35 may include, but is not limited to, a low refractive index layer.

### (Sixth Modification)

As illustrated in the cross-sectional view C of FIG. 3, the transparent conductive element 1 may further include an anti-reflection layer 36 on the surface of the substrate 11. The anti-reflection layer 36 is provided on one main surface of the substrate 11 which is on the opposite side to the main surface on which the transparent conductive film 12 is provided. Examples of the anti-reflection layer 36 to be used may include a moth-eye structure layer and a shape transfer anti-reflection layer (a shape transfer AR (Anti-reflection) layer).

### (Seventh Modification)

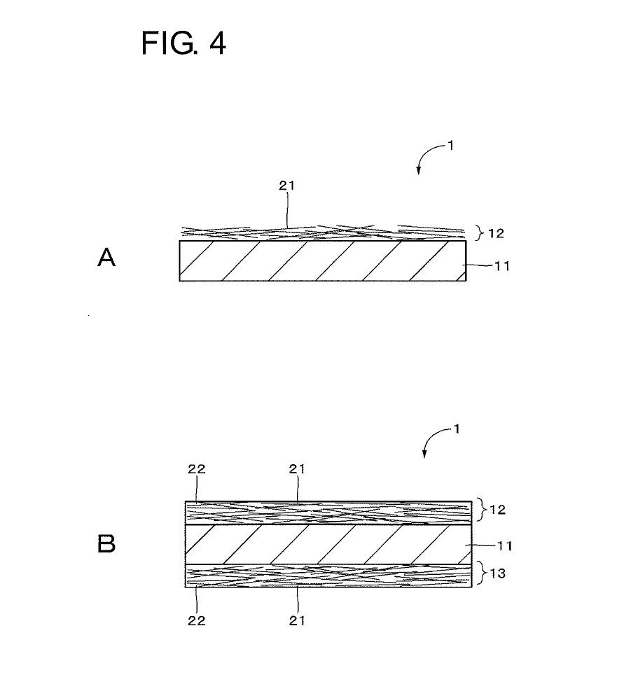

As illustrated in the cross-sectional view A of FIG. 4, the transparent conductive film 12 may have a configuration in which the resin material 22 is removed. On the surface of the substrate 11, the metal fillers 21 modified with the colored compound 23 and the thiols and/or sulfides are accumulated without being dispersed in the resin material 22. Then, the transparent conductive film 12 configured by accumulation of the metal fillers 21 is provided on the surface of the substrate 11 while maintaining the adhesion to the surface of the substrate 11. Such a configuration is preferably applied when the adhesion between the metal fillers 21 and between the metal filler 21 and the substrate 11 are favorable. Even in the transparent conductive element 1 having such a configuration, since the surface of the metal filler is modified with the colored compound 23 and the thiols and/or sulfides, the same effect as that of the transparent conductive element 1 configured as described in the first embodiment can be obtained.

### (Eighth Modification)

As illustrated in the cross-sectional view B of FIG. 4, the transparent conductive element 1 may further include a transparent conductive film 13 on the surface of the substrate 11. The transparent conductive film 13 is provided on one main surface of the substrate 11 which is on the opposite side to the main surface on which the transparent conductive film 12 is provided. As a configuration of the transparent conductive film 13, the same configuration as the transparent conductive film 12 in the above-described first embodiment may be adopted.

### 2. Second Embodiment

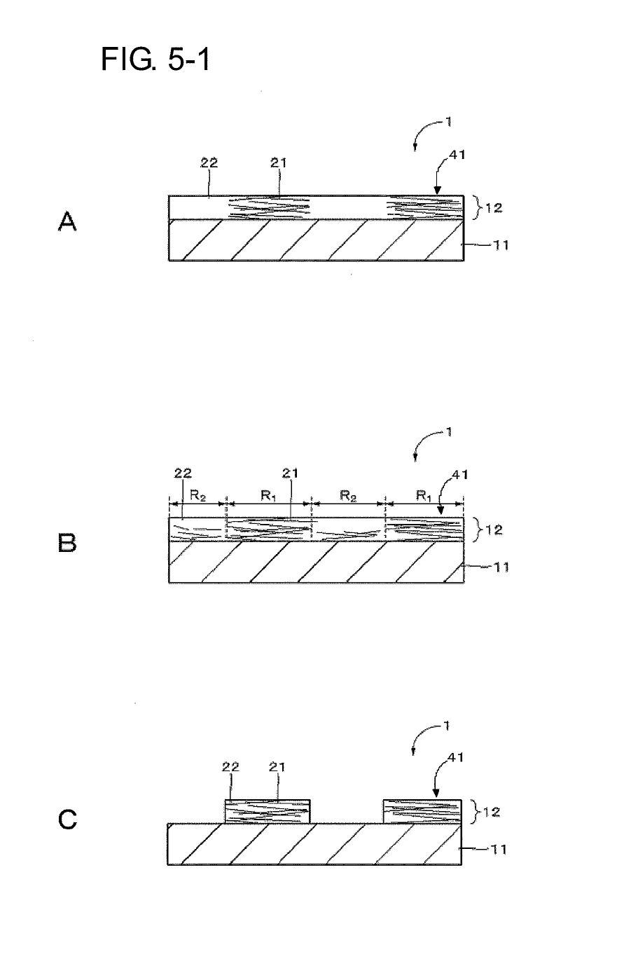

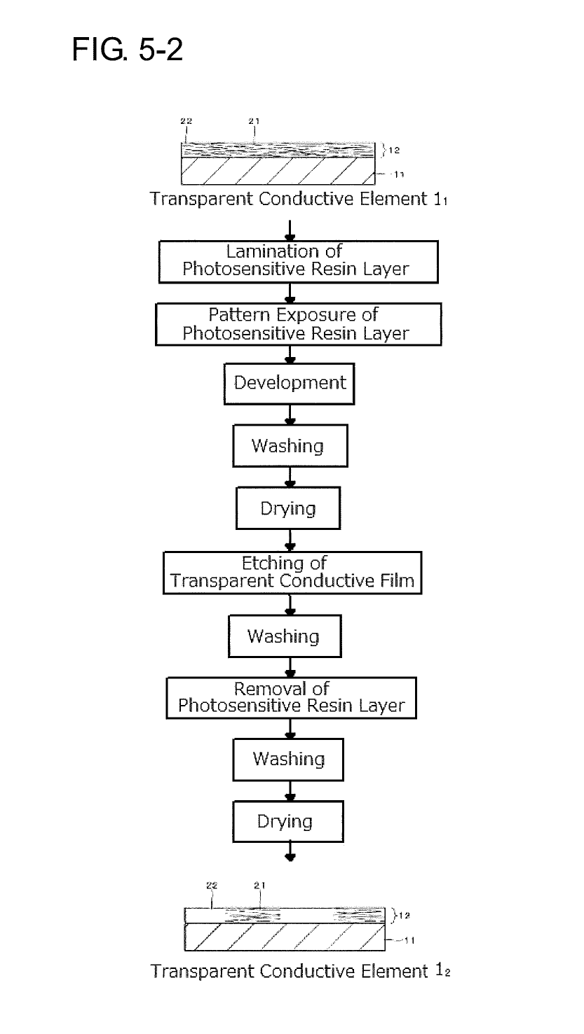

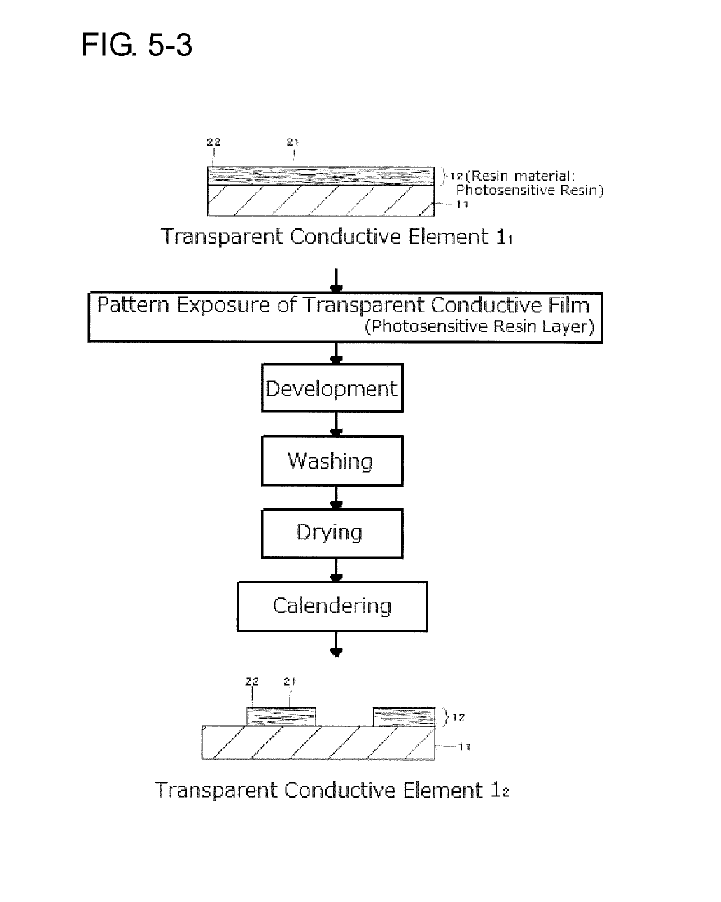

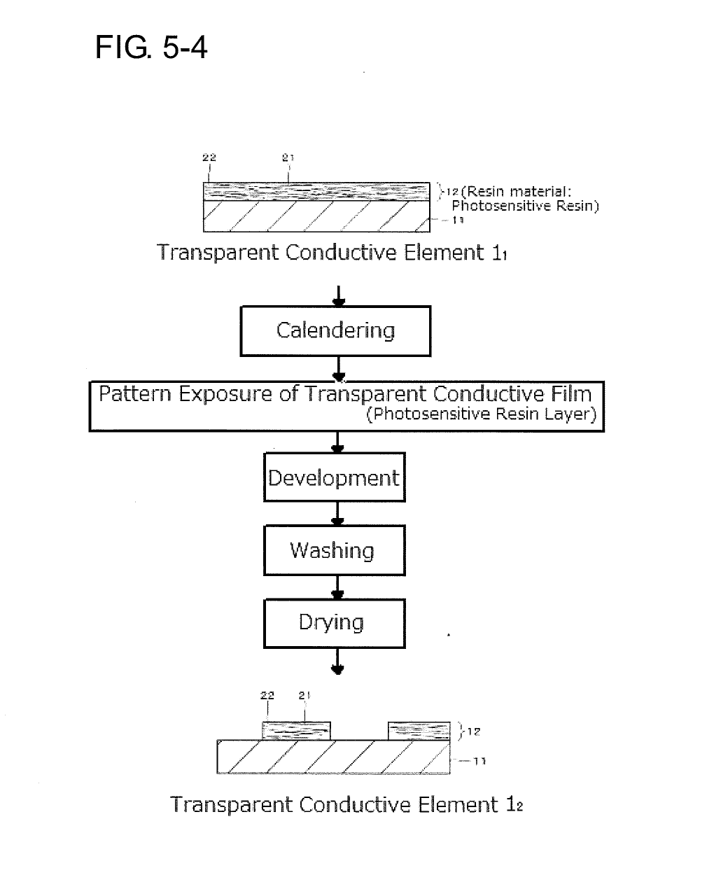

The cross-sectional view A of FIG. 5-1 illustrates an example of a configuration of a transparent conductive element according to a second embodiment of the present technique. A transparent conductive element 1 according to the second embodiment is, as illustrated in the cross-sectional view A of FIG. 5-1, different from the transparent conductive element 1 according to the first embodiment, in that the transparent conductive film 12 is patterned. The patterned transparent conductive film 12 constitutes, for example, an electrode 41 such as an X electrode or a Y electrode. Examples of the shape of the electrode 41 may include, but are not limited to, a stripe shape (linear shape), and a shape in which a plurality of pads (unit electrodes) each having a predetermined shape are linearly connected.

As a patterning method, for example, as illustrated in FIG. 5-2, a photosensitive resin layer is laminated on the surface of the transparent conductive film 12 of a transparent conductive element 1₁ according to the first embodiment, and then pattern exposure, development, washing, and drying are sequentially performed thereby to pattern a photosensitive resin film on the surface of the transparent conductive film 12.

Here, the pattern exposure may be either mask exposure or laser exposure. For the development, an alkaline aqueous solution (such as a sodium carbonate aqueous solution, a sodium hydrogen carbonate aqueous solution, and a tetramethylammonium hydroxide aqueous solution) or an acid aqueous solution (such as an acetic acid aqueous solution) is used depending on the type of the photosensitive resin film.

Next, the transparent conductive film 12 is etched using the patterned photosensitive resin layer as a mask. An etching solution is appropriately selected according to the types of the metal filler 21 and the type of the resin material 22 constituting the transparent conductive film 12. For example, the metal filler 21 is etched using an aqueous solution of copper chloride and hydrochloric acid. This is washed with water or the like, and the photosensitive resin layer on the surface is removed by an alkaline aqueous solution or the like. The obtained product is washed with water and dried again. Thus, a transparent conductive element 1₂ according to the second embodiment, having the patterned transparent conductive film 12, can be obtained.

When the resin material constituting the transparent conductive element obtained in the first embodiment is formed with a photosensitive resin, lamination and patterning of the photosensitive resin layer in the above-described process illustrated in FIG. 5-2 can be omitted, and as illustrated in the cross-sectional view C of FIG. 5-1, the resin layer 22 can also be patterned together with the metal filler 21. That is, as illustrated in FIG. 5-3, the transparent conductive element 1₁ can be directly pattern-exposed, and then sequentially subjected to the steps of development, washing, and drying to obtain the transparent conductive element 1₂ according to the second embodiment.

Here, the pattern exposure may also be either mask exposure or laser exposure. For the development, for example, an alkaline aqueous solution (such as a sodium carbonate aqueous solution, a sodium hydrogen carbonate aqueous solution, and a tetramethylammonium hydroxide aqueous solution) or an acidic aqueous solution (such as an acetic acid aqueous solution) is appropriately used depending on the types of the metal filler 21 and the resin material 22 constituting the transparent conductive film 12.

The washing can be performed using water or alcohol (for example, methanol, ethanol, n-propanol, i-propanol, n-butanol, i-butanol, sec-butanol and tert-butanol) as a washing liquid. The transparent conductive film 12 is immersed in the washing liquid, or the transparent conductive film 12 is showered with the washing liquid.

Here, it is preferred, in terms of improving the conductivity of the transparent conductive film 12, to perform calendering after the drying step in the manufacturing step illustrated in FIG. 5-3. Alternatively, as illustrated in FIG. 5-4, calendering may be performed before the pattern exposure step (that is, before the pattern exposure to be performed after applying a dispersion for forming a transparent conductive film to the substrate 11 and drying the applied substrate 11).

### (Modification)

As illustrated in the cross-sectional view B of FIG. 5-1, the transparent conductive film 12 may include conductive regions R₁ and insulating regions R₂ in an in-plane direction of the substrate 11. The conductive regions R₁ constitute the electrode 41 such as an X electrode or a Y electrode. On the other hand, the insulating regions R₂ constitute insulating parts that insulate between the conductive regions R₁. In the insulating region R₂, for example, at least the metal filler 21 is isolated from the conductive region R₁, and an insulated state is maintained. Examples of the method of isolating the metal filler 21 may include an etching method. In this case, the insulating regions R₂ are formed so as not to be completely etched, by adjusting the liquid composition, the treatment temperature, and the treatment time which are employed in the etching treatment of the transparent conductive film 12 (the development treatment thereof, when the resin constituting the transparent conductive film 12 includes a photosensitive resin). Thus, forming the insulating regions R₂ which are not completely etched enables invisibility of the electrode pattern to increase.

Also, configurations according to first to eighth modifications of the first embodiment described above may be applied to the transparent conductive element 1 according to the second embodiment and modifications thereof.

### 3. Third Embodiment

### Manufacturing Method of Transparent Conductive Element

Next, an example of the manufacturing method of the transparent conductive element will be described in which a dispersion film of the metal fillers 21 is formed, and then surface treatment with thiols, sulfides, or disulfides which are used as the colorless surface protective agent 24, and surface treatment with the colored compound 23 are sequentially performed to the metal filler 21 in the dispersion film.

### (3-1) Preparation of Dispersion of Metal Filler

First, a dispersion in which the metal fillers 21 are dispersed in a solvent is prepared. Here, a resin material (a binder) is added to the solvent together with the metal fillers 21. In this embodiment, the previously-described photosensitive resin can also be used as the resin material. Also, as necessary, a dispersant for improving dispersibility of the metal fillers 21 and other additives for improving adhesion and durability are mixed.

As the dispersion technique, stirring, ultrasonic dispersion, bead dispersion, kneading, homogenizer treatment, and the like can be preferably applied.

When the mass of the dispersion is assumed to be 100 parts by mass, the amount of the metal fillers 21 to be added in the dispersion is 0.01 to 10.00 parts by mass. When the amount thereof is less than 0.01 parts by mass, a sufficient basis weight (for example, 0.001 to 1.000 [g/m²]) of the metal fillers 21 in the resulting transparent conductive film 12 cannot be obtained. On the other hand, when the amount thereof is more than 10 parts by mass, the dispersibility of the metal fillers 21 tends to deteriorate. Also, when the dispersant is added to the dispersion, the amount of the dispersant added is preferably determined so that the conductivity of the resulting transparent conductive film 12 does not deteriorate.

Here, as the solvent to be used for preparing the dispersion described above, a solvent in which the metal fillers can be dispersed is used. For example, at least one or more selected from water, alcohols (for example, methanol, ethanol, n-propanol, i-propanol, n-butanol, i-butanol, sec-butanol, and tert-butanol), anones (for example, cyclohexanone and cyclopentanone), amides (for example, N,N-dimethylformamide: DMF), sulfides (for example, dimethyl sulfide), dimethyl sulfoxide (DMSO) and the like are used.

In order to suppress uneven drying and crack of the dispersion film formed using the dispersion, a high boiling point solvent can also be further added in the dispersion to control the speed of the solvent to evaporate from the dispersion. Examples of the high boiling point solvent may include butyl cellosolve, diacetone alcohol, butyl triglycol, propylene glycol monomethyl ether, propylene glycol monoethyl ether, ethylene glycol monoethyl ether, ethylene glycol monopropyl ether, ethylene glycol monoisopropyl ether, diethylene glycol monobutyl ether, diethylene glycol monoethyl ether, diethylene glycol monomethyl ether, diethylene glycol diethyl ether, dipropylene glycol monomethyl ether, tripropylene glycol monomethyl ether, propylene glycol monobutyl ether, propylene glycol isopropyl ether, dipropylene glycol isopropyl ether, tripropylene glycol isopropyl ether, and methyl glycol. These high boiling point solvents may be used alone or as a mixture of two or more.

### (3-2) Formation of Dispersion Film

Next, using the dispersion prepared as described above, a dispersion film in which the metal fillers 21 are dispersed is formed on the transparent substrate 11. The method of forming the dispersion film is not particularly limited, but a wet film forming method is preferred in view of physical properties, convenience, manufacturing costs, and the like. As the wet film forming method, a known method such as a coating method, a spray method, and a printing method is applied. The coating method is not particularly limited, and a known coating method can be used. Examples of the known coating method may include a microgravure coating method, a wire bar coating method, a direct gravure coating method, a die coating method, a dipping method, a spray coating method, a reverse roll coating method, a curtain coating method, a comma coating method, a knife coating method, and a spin coating method. Examples of the printing method may include letterpress, offset, gravure, intaglio, rubber plate, screen, and ink-jet printings.

In this state, the dispersion film in which the metal fillers 21 are dispersed in the solvent containing the uncured resin material (binder) 22 is formed.

### (3-3) Drying and Curing of Dispersion Film

Next, the solvent in the dispersion film formed on the substrate 11 is removed by drying. Removal of the solvent by drying may be performed by air drying or heat drying. Thereafter, curing treatment of the uncured resin material 22 is performed, so that the metal fillers 21 are dispersed in the cured resin material 22. Next, in order to reduce the sheet resistance value of the resultant transparent conductive film 12, pressurizing treatment by calendering may be performed as necessary.

### (3-4) Preparation of First Treatment Solution

At least one of thiols, sulfides, and disulfides which is used as the colorless surface protective agent 24 is dissolved in a solvent to prepare a treatment solution. The solvent is not particularly limited as long as the thiols, sulfides, or disulfides to be used can be dissolved in the solvent. Specific examples thereof may include dimethyl sulfoxide, N,N-dimethylformamide, ethanol, and water.

The concentration of thiols, sulfides, and disulfides which are used as the surface protective agent 24 is preferably 0.01% by mass or more, from the viewpoint of improving the adsorption speed of the thiols, sulfides, and disulfides to the surface of the metal filler. Here, the “concentration of thiols, sulfides, and disulfides” means the total value of the concentration of thiols, the concentration of sulfides, and the concentration of disulfides.

(3-5) Adsorption Treatment with Surface Protective Agent (thiols, sulfides, or disulfides)

Next, the dispersion film in which the resin material 22 is uncured or cured is brought into contact with the first treatment solution. When the first treatment solution comes into contact with the metal filler 21, the surface protective agent 24 composed of the thiols, sulfides, or disulfides is adsorbed to the metal filler 21 that is exposed at least on the surface of the dispersion film, through a thiol group, a sulfide group, or a disulfide group. Alternatively, the treatment solution swells the dispersion film, for example, so that adsorption also occurs on the surface of the metal filler 21 inside the dispersion film. Furthermore, the surface protective agent 24 preferentially is adsorbed to the crystal grain boundary or the portion not protected with the dispersant on the surface of the metal filler 21. At the same time, adsorption occurs even on the portion protected with the dispersant by substituting for the dispersant. Even after the adsorption treatment with the surface protective agent 24, the sheet resistance does not change at all, or hardly changes.

Specific examples of the above-described adsorption treatment may include an immersion method of immersing a dispersion film, in which the metal fillers 21 are dispersed, in the first treatment solution, and a coating method or a printing method of forming a liquid film of the first treatment solution on a dispersion film.

When the immersion method is applied, the first treatment solution is prepared in an amount that allows the dispersion film to be sufficiently immersed, and the dispersion film is immersed in the first treatment solution for 0.1 seconds to 48 hours. Meanwhile, by performing at least one of heating treatment and ultrasonic treatment, the adsorption speed of thiols, sulfides, or disulfides to the metal filler 21 can be increased. Following to the immersion, a step of washing the dispersion film with a good solvent of thiols, sulfides, or disulfides to remove the unadsorbed thiols, sulfides, or disulfides remaining in the dispersion film is performed as necessary.

When the coating method is applied, an appropriate method is selected from, for example, a microgravure coating method, a wire bar coating method, a direct gravure coating method, a die coating method, a dipping method, a spray coating method, a reverse roll coating method, a curtain coating method, a comma coating method, a knife coating method, and a spin coating method, to form a liquid film of the first treatment solution on the dispersion film.

When the printing method is applied, an appropriate method is selected from, for example, a letterpress printing method, an offset printing method, a gravure printing method, an intaglio printing method, a rubber plate printing method, an ink-jet method, and a screen printing method, to form a liquid film of the first treatment solution on the dispersion film.

When the coating method or the printing method is applied, by performing at least one of heating treatment and ultrasonic treatment in a state where the liquid film of a certain amount of the first treatment solution is formed on the dispersion film, the adsorption speed of the colored compound 23 to the metal filler 21 can be increased. Also, after a certain time has elapsed since the liquid film of the first treatment solution was formed, a step of washing the dispersion film with a good solvent of thiols, sulfides, or disulfides to remove the unadsorbed thiols, sulfides, or disulfides remaining in the dispersion film is performed as necessary.

In this case, formation of the liquid film of a certain amount of the first treatment solution does not need to be achieved by forming the liquid film once, and may be achieved by repeating the forming step and the washing step of the liquid film described above more than once.

### (3-6) Drying Treatment

Following to the adsorption treatment as described above, drying treatment of the dispersion film is performed. The drying treatment herein may be performed by air drying, or by heat drying in a heating device.

### (3-7) Preparation of Second Treatment Solution

A treatment solution containing the colored compound 23 is prepared. Here, for example, the colored compound 23 is dissolved in a solvent to prepare a second treatment solution. In such a second treatment solution, the concentration of the colored compound 23 is preferably higher in the adsorption treatment using the second treatment solution, from the viewpoint of improving the adsorption speed of the colored compound 23 to the metal filler 21. Specifically, the concentration of the colored compound 23 in the second treatment solution is preferably 0.01%; by mass or more. When the colored compound 23 is liquid at normal temperature, or when the colored compound 23 can be in a liquid state when heated at a temperature acceptable in the process, the liquid colored compound 23 may be used as it is as the second treatment solution.

The solvent used for preparation of the second treatment solution may be appropriately selected such that the colored compound 23 can be dissolved at a predetermined concentration. Specific examples thereof may include water, acetonitrile, 3-methoxypropionitrile, 3,3-dimethoxypropiononitrile, 3-ethoxypropionitrile, 3,3′-oxydipropionitrile, 3-aminopropionitrile, propionitrile, cyanoacetic acid propyl, 3-methoxypropyl isothiocyanate, 3-phenoxypropionitrile, p-anisidine 3-(phenylmethoxy)propanenitrile, methanol, ethanol, propanol, isopropyl alcohol, n-butanol, 2-butanol, isobutanol, t-butanol, ethylene glycol, triethylene glycol, 1-methoxy-ethanol, 1,1-dimethyl-2-methoxyethanol, 3-methoxy-1-propanol, dimethyl sulfoxide, benzene, toluene, o-xylene, m-xylene, p-xylene, chlorobenzene, dichlorobenzene, butyl acetate, ethyl acetate, cyclohexane, cyclohexanone, ethyl methyl ketone, acetone, and dimethylformamide. These solvents may be used alone or as a mixture of two or more.

### (3-8) Adsorption Treatment of Colored Compound

Next, the dispersion film in which the metal fillers 21 are dispersed in the resin material 22 that is before or after curing is brought into contacted with the second treatment solution in which the colored compound 23 is dissolved. Accordingly, the colored compound 23 in the second treatment solution is adsorbed to the metal filler 21 at least on the surface of the dispersion film, and preferably to the metal filler 21 on the surface of and inside the dispersion film.

Specific examples of the adsorption treatment may include an immersion method of immersing the dispersion film, in which the metal fillers 21 are dispersed, in the second treatment solution, and a coating method or a printing method of forming a liquid film of the second treatment solution on the dispersion film.

When the immersion method is applied, the second treatment solution is prepared in an amount that allows the dispersion film to be sufficiently immersed, and the dispersion film is immersed in the second treatment solution for 0.1 seconds to 48 hours. Meanwhile, by performing at least one of heat treatment and ultrasonic treatment, the adsorption speed of the colored compound 23 to the metal filler 21 can be increased. Following to the immersion, a step of washing the dispersion film with a good solvent of the colored compound 23 to remove the unadsorbed colored compound 23 remaining in the dispersion film is performed as necessary.

When the coating method is applied, an appropriate method is selected from, for example, a microgravure coating method, a wire bar coating method, a direct gravure coating method, a die coating method, a dipping method, a spray coating method, a reverse roll coating method, a curtain coating method, a comma coating method, a knife coating method, and a spin coating method, to form a liquid film of the second treatment solution on the dispersion film. When the printing method is applied, an appropriate method is selected from, for example, a letterpress printing method, an offset printing method, a gravure printing method, an intaglio printing method, a rubber plate printing method, an ink-jet method, and a screen printing method, to form a liquid film of the second treatment solution on the dispersion film.

When the coating method or the printing method is applied, by performing at least one of heating treatment and ultrasonic treatment in a state where the liquid film of a certain amount of the second treatment solution is formed on the dispersion film, the adsorption speed of the colored compound 23 to the metal filler 21 can be increased. Also, after a certain time has elapsed since the liquid film of the second treatment solution was formed, a step of washing the dispersion film with a good solvent of the colored compound 23 to remove the unadsorbed colored compound 23 remaining in the dispersion film is performed as necessary.

In this case, formation of the liquid film of a certain amount of the second treatment solution does not need to be achieved by forming the liquid film once, and may be achieved by repeating the forming step and the washing step of the liquid film described above more than once.

### (3-9) Drying Treatment

Following to the adsorption treatment as described above, drying treatment of the transparent conductive film 12 is performed. The drying treatment herein may be performed by air drying, or by heat drying in a heating device. Thus, the intended transparent conductive element 1 is obtained.

### (3-10) Others

As described in the modification of the first embodiment, when the transparent conductive film 1 in which the overcoat layer 31 is provided on the top of the transparent conductive film 12 is prepared, a step of forming the overcoat layer 31 on the top of the transparent conductive film 12 may be further performed. Also, when the transparent conductive film 1 in which the anchor layer 32 is provided between the substrate 11 and the transparent conductive film 12 is prepared, the anchor layer 32 is formed on the substrate 11 prior to the formation of the dispersion film. Thereafter, a step of forming the dispersion film on the anchor layer 32 and a subsequent step may be performed.

When the transparent conductive film 12 configured without using the resin material 22 is prepared (see the cross-sectional view A of FIG. 4), the dispersion is prepared without the resin material 22 and with a metal filler and a solvent, and a liquid film of the dispersion is formed on the substrate 11. Next, the solvent is removed from the liquid film formed on the substrate 11, so that the metal fillers 21 are accumulated in a state of being uniformly dispersed in a portion where the liquid film of the dispersion was formed on the substrate 11. Thus, a dispersion film constituted by the metal filler 21 is formed. After that, adsorption treatment may be performed by sequentially bringing this dispersion film into contact with the first treatment solution and the second treatment solution in the same procedure as the above-described procedure.

### [Surface Modification of Metal Filler]

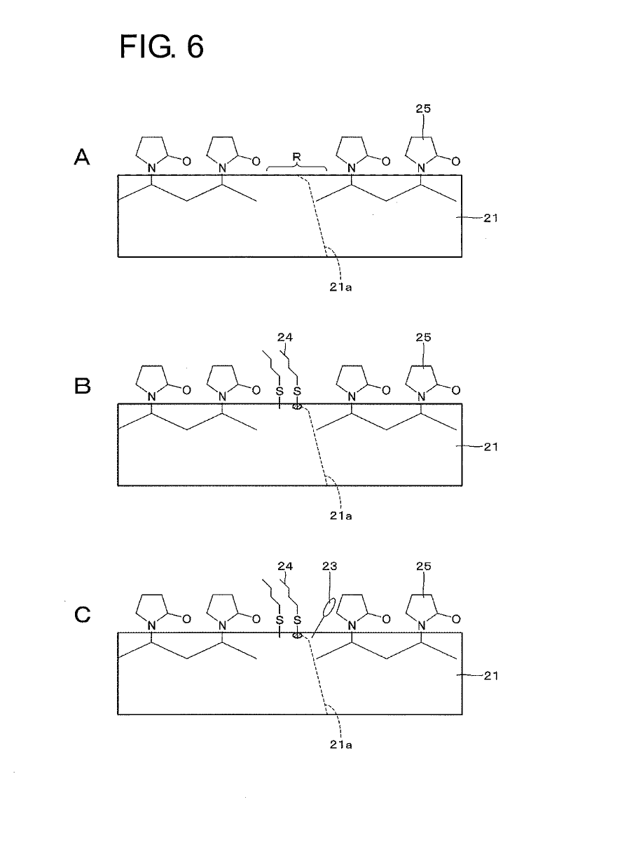

Next, by referring to FIG. 6, an example of the process of surface modification with the colored compound 23 and the colorless surface protective agent (thiols, sulfides, and disulfides) 24 will be described.

First, at the stage where the dispersion film is formed, a crystal grain boundary 21a and a portion R not protected by the dispersant 25 (a portion where a metal surface is exposed) exist in the metal filler 21 contained in the dispersion film, as illustrated in the cross-sectional view of FIG. 6A.

Next, when the surface of the metal filler 21 is modified with the surface protective agent 24, the surface protective agents 24 are adsorbed to the crystal grain boundary 21a and the portion R not protected by the dispersant 25, as illustrated in the cross-sectional view B of FIG. 6.

Next, when the surface of the metal filler 21 is modified with the colored compound 23, the colored compound 23 is adsorbed to a portion to which the surface protective agent 24 is not adsorbed to the surface of the metal filler 21, through the functional group [X] by a covalent bond, a coordinate bond or the like, as illustrated in the cross-sectional view C of FIG. 6. The adsorption between the surface protective agent 24 and the surface of the metal filler 21 is strong, and is hardly substituted by the colored compound 23. In the portion protected by the dispersant 25, the colored compound 23 is substituted for the dispersant 25 and is adsorbed to the portion.

By modifying the surface of the metal filler 21 with the surface protective agent 24 as described above, the increase in sheet resistance is suppressed even when the metal filler 21 is surface-treated with the colored compound 23 having a sulfo group, an amino group, a carboxyl group, a phosphate group, or the like as the functional group [X].

### [Effects]

According to the manufacturing method of the second embodiment described above, the transparent conductive film 12 having a configuration in which the surface of the metal filler is modified with the surface protective agent 24 and the colored compound 23 can be manufactured at low cost by a simple method without using a vacuum step.

### [Modifications]

### (First Modification)

The manufacturing method of the transparent conductive element according to the third embodiment described above may further include a step of patterning the transparent conductive film 12 to form an electrode pattern. Examples of the patterning method may include a method of etching the dispersion film or the transparent conductive film 12 into a pattern in the step of or after drying or curing the dispersion film, in the same manner as the patterning in the manufacturing method of the transparent conductive element according to the second embodiment. In this case, complete etching of completely removing the transparent conductive film 12 in the region other than the electrode pattern in the dispersion film or the transparent conductive film 12 may not be performed, but partial etching may be performed for patterning so that the metal filler 21 is at least isolated to become in an insulated state (see the cross-sectional view of FIG. 5-1B).

Also, in place of the above-described patterning method, for example, a patterned dispersion film may be previously formed by a printing method in the formation step of the dispersion film. Examples of the printing method to be used may include a letterpress printing method, an offset printing method, a gravure printing method, an intaglio printing method, a rubber plate printing method, an ink-jet method, and a screen printing method.

### (Second Modification)

In the manufacturing method of the transparent conductive element according to the third embodiment described above, a treatment solution in which the surface protective agent (thiols, sulfides, or disulfides) 24 and the colored compound 23 are dissolved in the same solvent may be used in place of the first treatment solution and the second treatment solution. Accordingly, the number of steps can be reduced.

The solvent is not particularly limited, and may be any solvent in which the surface protective agent 24 and the colored compound 23 can be dissolved. Specific examples thereof may include dimethyl sulfoxide, N,N-dimethylformamide, ethanol, and water.

The concentration of the surface protective agent (thiols, sulfides, and disulfides) 24 is preferably 0.01% by mass or more, from the viewpoint of improving the adsorption speed of the thiols, sulfides, or disulfides to the surface of the metal filler 21. Here, the “concentration of thiols, sulfides, and disulfides” means the total value of the concentration of thiols, the concentration of sulfides, and the concentration of disulfides. The concentration of the colored compound 23 is preferably 0.01% by mass or more, from the viewpoint of improving the adsorption speed of the dye to the surface of the metal filler. The ratio between the concentration of thiols, sulfides, and disulfides and the concentration of the colored compound 23 (=“concentration of thiols, sulfides, and disulfides”/“concentration of the colored compound 23”) is preferably set in an appropriate manner at 0.001 or more and 1000 or less depending on the designed values of the sheet resistance and the reflection L. When the concentration ratio is less than 0.001, the protection effect by thiols and/or sulfides becomes insufficient, thereby increasing the sheet resistance. On the other hand, when the concentration ratio is more than 1000, the colored compound 23 tends to become unlikely to be adsorbed to the surface of the metal filler 21, causing a tendency of inhibiting the decrease in the reflection L.

Here, the step of adsorption treatment can be the same as the adsorption treatment of the surface protective agent 24 or the adsorption step of the colored compound 23 in the second embodiment described above. The drying step can also be the same as the drying step of the surface protective agent 24 or the drying step of the colored compound 23 according to the second embodiment described above.

### 4. Fourth Embodiment

Next, as an example of the manufacturing method of the transparent conductive element, a method of modifying the surface of the metal filler 21 with the surface protective agent 24 (thiols, sulfides, or disulfides) and the colored compound 23 and then forming a dispersion film of the metal filler 21 will be described.

### (Preparation of Dispersion)

First, the surface protective agent 24 (thiols, sulfides, or disulfides) and the colored compound 23 are added to a dispersion of the metal filler 21 to thereby previously modify the surface of the metal filler 21 with the surface protective agent 24 and the colored compound 23. In order to obtain the protection effect by the surface protective agent 24, it is preferred that the surface protective agent 24 be added in advance to modify the surface of the metal filler 21 with the surface protective agent 24, and then the colored compound 23 be added to modify the surface of the metal filler with the surface protective agent 24 and the colored compound 23.

The concentration of the colored compound 23 to the dispersion is preferably 0.0001% by mass or more and 0.1% by mass or less. When the concentration is lower than 0.0001% by mass, the reflection L reduction effect is not sufficient. On the other hand, when the concentration is higher than 0.1% by mass, the metal fillers 21 tend to aggregate in the dispersion, causing deterioration in the sheet resistance value and the total light transmittance in the manufactured transparent conductive film 12.

The ratio between the concentration of the surface protective agent (thiols, sulfides, and disulfides) 24 and the concentration of the colored compound 23 is preferably set in an appropriate manner at 0.001 or more and 1000 or loess depending on the designed values of the sheet resistance and the reflection L. When the concentration ratio is less than 0.001, the protection effect by the surface protective agent 24 becomes insufficient, thereby increasing the sheet resistance. On the other hand, when the concentration ratio is more than 1000, the colored compound 23 tends to become unlikely to adsorb to the surface of the metal filler 21, causing a tendency of the reflection L to decrease. Here, the surface protective agent (thiols, sulfides, and disulfides) 24 means the total value of the concentration of thiols, the concentration of sulfides and the concentration of disulfides.

### [Formation of Dispersion Film]

Next, using the dispersion prepared as described above, a dispersion film is formed on the substrate 11. This dispersion film is a film in which the metal fillers 21 modified with the colored compound 23 and the surface protective agent 24 are dispersed in a solvent, and also contains the uncured resin material 22 as necessary. Although the formation method of such a dispersion film is not particularly limited, examples thereof may include an immersion method and a coating method.

### [Drying and Curing of Dispersion Film]

Next, the solvent in the dispersion film formed on the substrate 11 is removed by drying. Thereafter, curing treatment of the uncured resin material 22 is performed. Accordingly, the transparent conductive film 12, in which the metal fillers 21 surface-modified with the colored compound 23 and the surface protective agent 24 are dispersed, is obtained. Here, the removal of the solvent by drying, and the curing treatment of the uncured resin material 22 are performed in the same manner as that in the third embodiment described above. Thereafter, in order to reduce the sheet resistance value of the resultant transparent conductive film 12, pressurizing treatment by calendering may be performed as necessary. Thus, the intended transparent conductive element 1 is obtained.

### (Others)

The above-described method includes: reacting the metal filler 21 with the surface protective agent 24 and the colored compound 23 to prepare a dispersion of the metal fillers 21 modified with the surface protective agent 24 and the colored compound 23; allowing this dispersion to contain the uncured resin material 22 as necessary; and film-forming this dispersion on the substrate 11 to form the transparent conductive film 12. However, other than this, the transparent conductive element 1 according to the present invention may be manufactured by preparing a dispersion containing the metal filler 21, the surface protective agent 24, the colored compound 23, and the resin material 22 at the same time, film-forming this dispersion on the substrate 11 to form a transparent conductive film, and patterning the formed transparent conductive film. In these cases, a photosensitive resin may be used as the resin material 22.

### [Effects]

In the manufacturing method according to the fourth embodiment, the number of manufacturing steps can be reduced compared to the manufacturing method according to the third embodiment.

### 5. Fifth Embodiment

### Configuration of Information Input Device

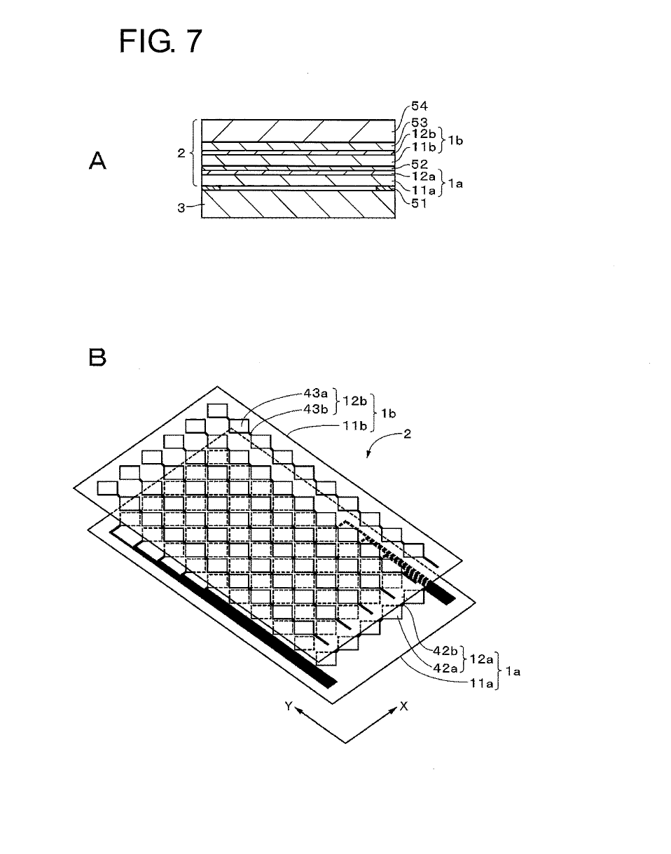

The cross-sectional view A of FIG. 7 is a cross-sectional view illustrating an example of a configuration of an information input device according to a fifth embodiment of the present technique. As illustrated in the cross-sectional view A of FIG. 7, an information input device 2 is provided on a display surface of a display device 3. The information input device 2 is, for example, bonded to the display screen of the display device 3 via a bonding layer 51. The bonding layer 51 may be provided only on the margins of the display screen of the display device 3 and the back surface of the information input device 2. As the bonding layer 51, for example, an adhesive paste and an adhesive tape are used. As described herein, the surface on the touch screen (the information input screen) side where information is input with a finger, a pen, or the like is referred to as a “surface”, and the surface on the opposite side to the “surface” is referred to as a “back surface”.

### (Display Device)

Although the display device 3 to which the information input device 2 is applied is not particularly limited, examples thereof may include various display devices such as a liquid crystal display, a cathode ray tube (CRT) display, a plasma display panel (PDP), an electroluminescence (EL) display, and a surface-conduction electron-emitter display (SED).

### (Information Input Device)

The information input device 2 is a so-called projection-type capacitive touch panel, and includes a first transparent conductive element 1a, and a second transparent conductive element 1b provided on the surface of the first transparent conductive element 1a. The first transparent conductive element 1a and the second transparent conductive element 1b are bonded to each other via a bonding layer 52.

Also, as necessary, a protective layer (optical layer) 54 may be further provided on the surface of the second transparent conductive element 1b. An example of the protective layer 54 includes a top plate made of glass or plastics. The protective layer 54 and the second transparent conductive element 1b are, for example, bonded to each other via a bonding layer 53. The protective layer 54 is not limited to this example, and can be a ceramic coat (an overcoat) such as SiO₂.

### (First Transparent Conductive Element)

The cross-sectional view B of FIG. 7 is an exploded perspective view illustrating an example of a configuration of the information input device according to the second embodiment of the present technique. As described herein, two directions orthogonal to each other within the planes of the first transparent conductive element 1a and the second transparent conductive element 1b are defined as an X-axis direction and a Y-axis direction.

The first transparent conductive element 1a includes a substrate 11a, and a transparent conductive film 12a provided on the surface of the substrate 11a. The transparent conductive film 12a is patterned, and constitutes an X electrode. The second transparent conductive element 1b includes a substrate 11b, and a transparent conductive film 12b provided on the surface of the substrate 11b. The transparent conductive film 12b is patterned, and constitutes a Y electrode.

While the X electrode extends in the X-axis direction (first direction) on the surface of the substrate 11a, the Y electrode extends toward the Y-axis direction (second direction) on the surface of the substrate 11b. Thus, the X electrode and the Y electrode intersect each other in an orthogonal manner.

The X electrode constituted by the transparent conductive film 12a includes a plurality of pads (first unit electrodes) 42a, and a plurality of connections (first connections) 42b that connect the plurality of pads 42a to each other. The connections 42b extend in the X-axis direction, and connect the ends of the adjacent pads 42a to each other. The pads 42a and the connections 42b are integrally formed.

The Y electrode constituted by the transparent conductive film 12b includes a plurality of pads (second unit electrodes) 43a, and a plurality of connections (second connections) 43b that connect the plurality of pads 43a to each other. The connections 43b extend in the Y-axis direction, and connect the ends of the neighboring pads 43a to each other. The pads 43a and the connections 43b are integrally formed.

The X electrode and the Y electrode are preferably configured such that when the information input device 2 is viewed from the touch screen side, the pads 42a and the pads 43a appear as a state of being wholly spread on one main surface of the information input device 2 without being superimposed on each other so as to be closely packed. This is because the reflectivity within the plane of the touch screen of the information input device 2 can be generally uniform.

Here, the description has been made on the configuration of the X electrode and the Y electrode as having a shape in which the pads (unit electrode bodies) 42a and 43a with a predetermined shape are linearly connected to each other. However, the shape of the X electrode and the Y electrode is not limited to this example. For example, a possible example of the shape of the X electrode and the Y electrode to be employed includes a stripe shape (liner shape). The first transparent conductive element 1a and the second transparent conductive element 1b are similar to the transparent conductive element 1 according to the second embodiment except for the above-described aspects.

### [Effects]

In the information input device 2 according to the fifth embodiment, the transparent conductive film 12 described in the second embodiment in which diffuse reflection of light is inhibited is used as the X electrode and the Y electrode. Accordingly, the X electrode and the Y electrode which are patterned are inhibited from being visually recognized through diffuse reflection of outside light. Also, when such an information input device 2 is arranged on the display screen of the display panel 3, display in which milky appearance during black display is inhibited is enabled. The milky appearance is caused by diffused reflection of outside light on the X electrode and the Y electrode disposed in the information input device 2.

The present technique is not limited to the information input device 2 described above, and can be widely applied to information input devices provided with the transparent conductive film 12. For example, a resistive film type touch panel may be included. Even with such a configuration, the effect similar to the information input device 2 according to the fifth embodiment can be obtained.

### [Modifications]

### (First Modification)

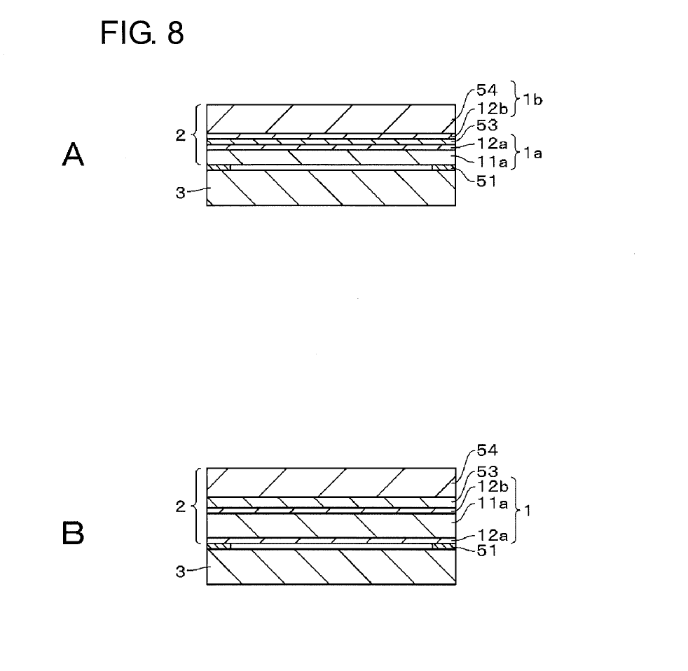

The cross-sectional view A of FIG. 8 illustrates an example of a configuration of an information input device according to a first modification. A first transparent conductive element 1a includes a substrate 11a, and a transparent conductive film 12a provided on the surface of the substrate 11a. A second transparent conductive element 1b includes a protective layer 54, and a transparent conductive film 12b provided on the back surface of the protective layer 54. The first transparent conductive element 1a and the second transparent conductive element 1b are bonded to each other through a bonding layer 53 in such a manner that the transparent conductive films 12a and 12b are opposed to each other.

### (Second Modification)

The cross-sectional view B of FIG. 8 illustrates an example of a configuration of an information input device according to a second modification. A transparent conductive element 1 includes a substrate 11a, a transparent conductive film 12a provided on the back surface of the substrate 11a, and a transparent conductive film 12b provided on the surface of the substrate 11a. The transparent conductive element 1 and a protective layer 54 are bonded together through a bonding layer 53.

### (Third Modification)

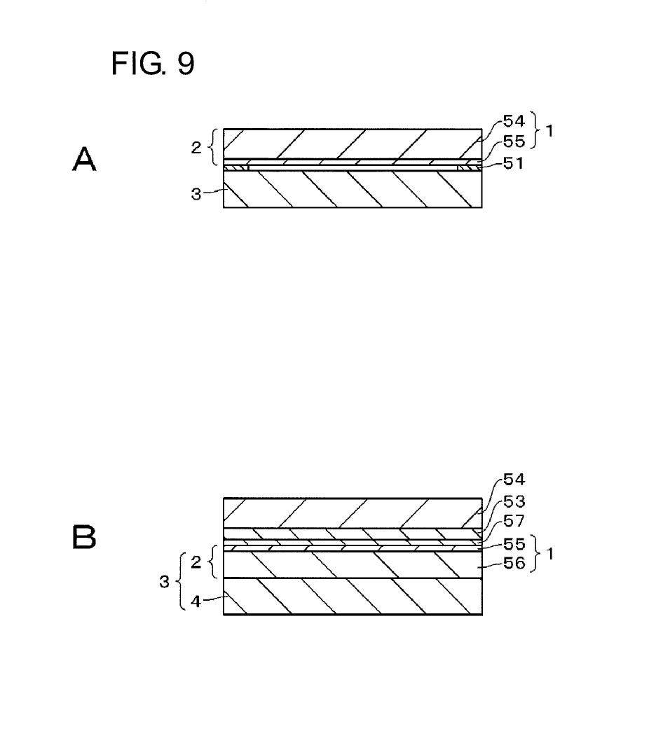

The cross-sectional view A of FIG. 9 illustrates an example of a configuration of an information input device according to a third modification. A transparent conductive element 1 includes a protective layer 54, and an electrode pattern part 55 directly provided on the back surface of the protective layer 54. The electrode pattern part 55 includes a transparent conductive film 12a as an X electrode and a transparent conductive film 12b as a Y electrode. The transparent conductive film 12a and the transparent conductive film 12b are directly formed on the back surface of the protective layer 54. Alternatively, the transparent conductive film 12a as the X electrode and the transparent conductive film 12b as the Y electrode may be configured to be laminated to each other through an insulating layer.

### (Fourth Modification)

The cross-sectional view B of FIG. 9 illustrates an example of a configuration of a display device according to a fourth modification. A display device 3 includes a display panel unit 4 such as a liquid crystal panel, a cover layer 56 such as a cover glass disposed on the surface of the display panel unit 4, an electrode pattern part 55 disposed on the surface of the cover layer 56, and a polarizer 57 provided on the surface of the electrode pattern part. Furthermore, a protective layer 54 is provided on the surface of the polarizer 57 through a bonding layer 53. The electrode pattern part 55 includes a transparent conductive film 12a as an X electrode and a transparent conductive film 12b as a Y electrode. The transparent conductive film 12a and the transparent conductive film 12b may be directly formed on the surface of the cover layer 56. Alternatively, the transparent conductive film 12a as the X electrode and the transparent conductive film 12b as the Y electrode may be configured to be laminated to each other through an insulating layer.

### 6. Sixth Embodiment

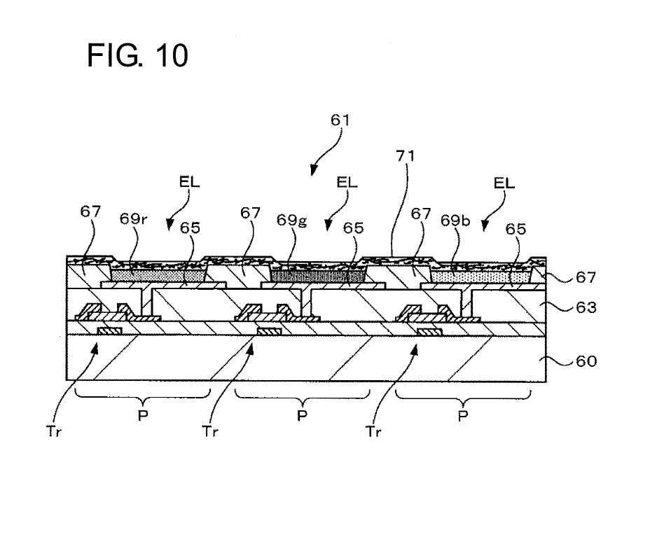

FIG. 10 illustrates a cross-sectional view of a main part of a display device including a transparent conductive film. A display device 61 illustrated in this figure is an active matrix-type organic EL display device including an organic electroluminescence element EL.

As illustrated in FIG. 10, the display device 61 is an active matrix-type display device 61 in which a thin film transistor Tr as a pixel circuit and an organic electroluminescence element EL connected to the pixel circuit are arranged in each pixel P on a substrate 60.

The top of the substrate 60 on which the thin film transistors Tr are arranged is covered with a planarization insulating film 63. On top of this planarization insulating film 63, pixel electrodes 65 connected to the thin film transistors Tr are arranged and formed through connection holes provided in the planarization insulating film 63. The pixel electrode 65 constitutes an anode (or a cathode).

The periphery of each pixel electrode 65 is covered with a window insulating film 67 to be element-isolated. The top of the element-separated pixel electrode 65 is covered with an organic luminescence function layer 69r, 69g, or 69b for each color. Furthermore, a common electrode 71 covering these organic luminescence function layers is provided. Each organic luminescence function layer 69r, 69g, or 69b has a layered structure including at least an organic luminescent layer. In the common electrode 71 covering these organic luminescence function layers, a layer in contact with each organic luminescence functional layer 69r, 69g, or 69b is formed as, for example, a cathode (or an anode). Also, the common electrode 71 is formed as light transmitting electrode which takes out the luminescent light generated in each organic luminescence function layer 69r, 69g, or 69b as a whole. The transparent conductive film 12 according to the second embodiment is used for at least one of the layers of such a common electrode 71.

As described above, the organic electroluminescence element EL is formed in each pixel P part including the organic luminescence function layer 69r, 69g, or 69b between the pixel electrode 65 and the common electrode 71. Although not illustrated in the figure here, a protective layer is further provided on the substrate 60 on which these organic electroluminescence elements EL are formed, and a sealing substrate is bonded thereon through an adhesive to constitute the display device 61.

### [Effects]

In the display device 61 according to the sixth embodiment described above, the transparent conductive film 12 according to the second embodiment is provided as the common electrode 71 provided on the display screen side that is a side of taking out the luminescent light. Accordingly, when the luminescent light generated in each organic luminescence function layer 69r, 69g, or 69b is taken out from the common electrode 71 side, milky appearance caused by diffused reflection of outside light on the common electrode 71 is inhibited, and high contrast display is enabled even in the outside light environment.

Here, the information input device 2 may be disposed on the display screen side of this display device 61 similarly to the fifth embodiment. Even in this case, the effect similar to that in the fifth embodiment can be obtained.

### 7. Seventh Embodiment

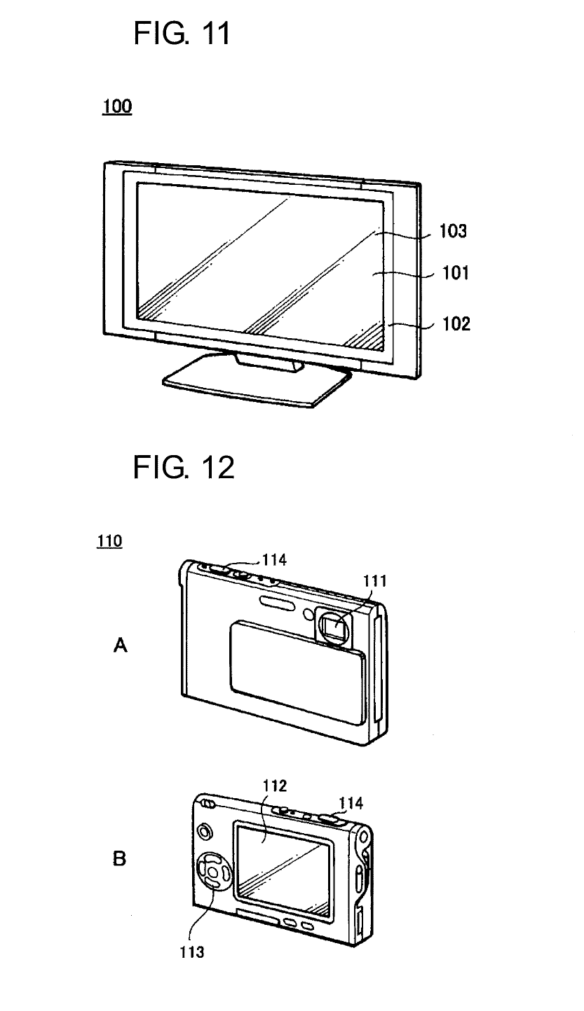

FIG. 11 to FIG. 15 illustrate an example of an electronic instrument in which the display device 3 provided with the information input device 2 according to the fifth embodiment or the display device 61 according to the sixth embodiment is applied to the display part. Application examples of the electronic instrument according to the present technique will be described below.

FIG. 11 is a perspective view illustrating a television set to which the present technique is applied. A television set 100 according to the present application example includes a display unit 101 constituted by a front panel 102, a filter glass 103 and the like. As the display unit 101, the display device described above is applied.

FIG. 12 illustrate a digital camera to which the present technique is applied. A perspective view A of FIG. 12 is a view seen from a front side, and a perspective view B of FIG. 12 is a view seen from a back side. A digital camera 110 according to the present application example includes a luminescence unit 111 for flash, a display unit 112, a menu switch 113, a shutter button 114 and the like. As the display unit 112, the display device described above is applied.

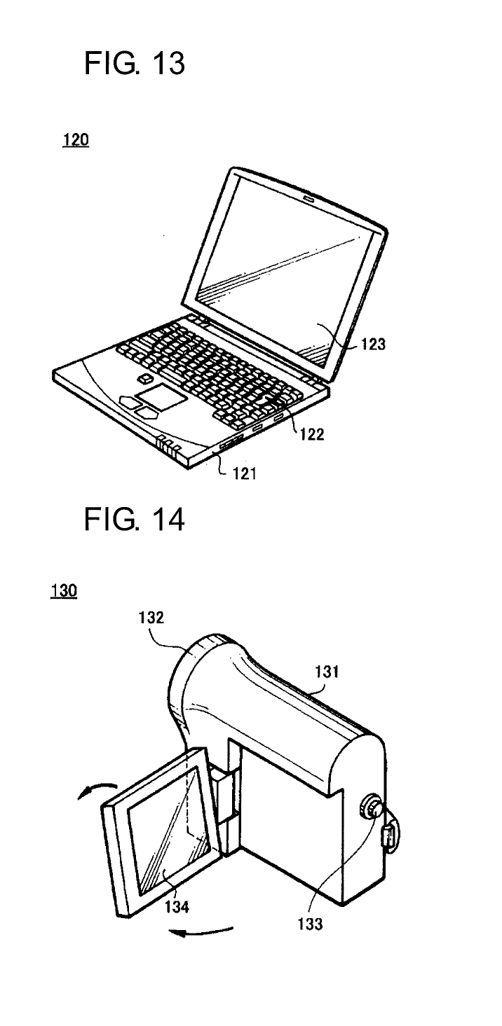

FIG. 13 is a perspective view illustrating a notebook-type personal computer to which the present technique is applied. A notebook-type personal computer 120 according to the present application example includes a body 121, a keyboard 122 that is operated when inputting a letter or the like, a display unit 123 that displays an image, and the like. As the display unit 123, the display device described above is applied.

FIG. 14 is a perspective view illustrating a video camera to which the present technique is applied. A video camera 130 according to the present application example includes a body part 131, a lens 132 that photographs a subject and is disposed on the side facing the front, a start/stop switch 133 for taking pictures, a display unit 134, and the like. As the display unit 134, the display device described earlier is applied.

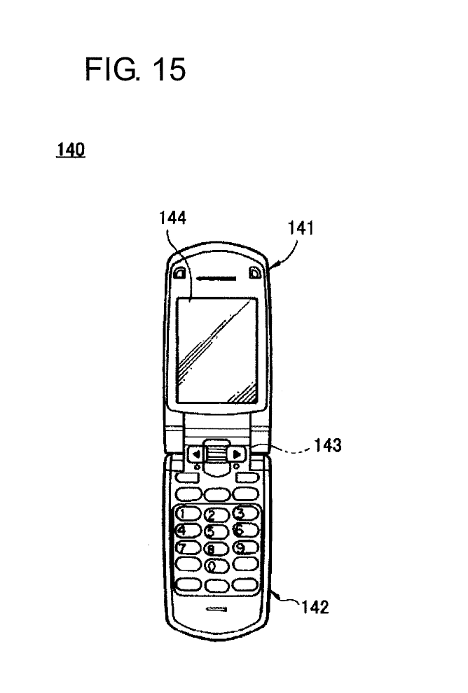

FIG. 15 is a front view illustrating a mobile terminal device to which the present technique is applied, for example, a mobile phone. A mobile phone 140 according to the present application example includes an upper side casing 141, a lower side casing 142, a linking part (a hinge part in this case) 143, and a display unit 144. As the display unit 144, the display device described earlier is applied.

Even in the case of each electronic instrument as above, high contrast display is enabled even in the outside light environment, by using the display device 3 according to the fifth embodiment or the display device 61 according to the sixth embodiment to the display part.

### EXAMPLES

Although the present technique will be specifically described below with reference to Examples, the present technique is not limited to these Examples.

### Examples 1 to 4 and Comparative Examples 1 to 3

First, a silver nanowire was prepared as a metal filler. Here, a silver nanowire having a diameter of 30 nm and a length of 10 μm was prepared, by an existing method referring to a literature (“ACS Nano” 2010, VOL. 4, NO. 5, p. 2955-2963).

Next, the following materials were placed in ethanol together with the prepared silver nanowires, and the silver nanowires were dispersed in ethanol using ultrasonic waves to prepare a dispersion. Silver nanowires: 0.28% by mass

Hydroxypropyl methyl cellulose manufactured by Aldrich (a transparent resin material): 0.83% by mass
Duranate D101 (a resin curing agent) manufactured by Asahi Kasei: 0.083% by mass
Neostan U100 (a cure promoting catalyst) manufactured by
Nitto Kasei: 0.0025% by mass
Ethanol (solvent): 98.8045% by mass

A transparent substrate was coated with the prepared dispersion using a No. 8 coil bar to form a dispersion film. The basis weight of the silver nanowires was set to be about 0.05 g/m². As the transparent substrate, a PET (U34, manufactured by Toray Industries, Inc.) having a thickness of 125 μm was used. Next, heating treatment was performed in the atmosphere at 80° C. for 2 minutes to dry and remove the solvent in the dispersion film. Subsequently, heating treatment was further performed in the atmosphere at 150° C. for 30 minutes to cure the transparent resin material in the dispersion film (Comparative Example 1).

Furthermore, 6-hydroxy-1-hexanethiol (Aldrich Co.) was dissolved in N,N-dimethylformamide to have a concentration of 0.25% by mass. To this solution, the dispersion film of the silver nanowires prepared in the same manner as that in Comparative Example 1 above was immersed at room temperature for 5 minutes, to allow 6-hydroxy-1-hexanethiol in the solution to be adsorbed to the silver nanowire in the dispersion film (Comparative Example 2).

Next, Lanyl Black BG E/C (Okamoto Dyestuff Co., Ltd.) as a dye was dissolved in dimethyl sulfoxide to have a concentration of 0.25% by mass. This solution was heated to 80° C., and the dispersion film of the silver nanowires which was prepared in the same manner as that in Comparative Example 2 above and to which 6-hydroxy-1-hexanethiol was adsorbed was immersed to the heated solution, to allow the dye in the solution to be adsorbed to the silver nanowire in the dispersion film. As a result of this adsorption treatment, transparent conductive films of Examples 1 to 4 were obtained. The adsorption treatment time (immersion time) was set to be 15 minutes in Example 1, 20 minutes in Example 2, 25 minutes in Example 3, and 30 minutes in Example 4.

Also, as Comparative Example 3, a transparent conductive film was obtained by performing adsorption treatment in which a dispersion film of silver nanowires was immersed in the above-described treatment solution of Lanyl Black BG E/C at room temperature for 30 minutes to allow the dye in this solution to be adsorbed to the silver nanowire in the dispersion film of the silver nanowires prepared in the same manner as that in Comparative Example 1 above, without performing surface treatment to the dispersion film of the silver nanowires with 6-hydroxy-1-hexanethiol.

### Examples 5 and 6

As thiols, 1-dodecanethiol (Aldrich Co.) was used. The adsorption treatment condition was set to be room temperature and 5 minutes in Example 5, and room temperature and one minute in Example 6. As a dye, Lanyl Black BG E/C (Okamoto Dyestuff.) was used. The adsorption treatment condition was set to be 80° C. and 30 minutes in both Examples 5 and 6. Transparent conductive films were obtained in the same manner as that in Example 1 except the above.

### Examples 7 and 8, and Comparative Example 4

As thiols, 1-dodecanethiol was used. The adsorption treatment condition was set to be room temperature and 5 minutes in both Examples 7 and 8. Isolan Black NHF-S(Okamoto Dyestuff.) as a dye was dissolved in dimethyl sulfoxide at 0.25% by mass. The adsorption treatment condition was set to be 80° C. and 30 minutes in Example 7, and 80° C. and 90 minutes in Example 8. Transparent conductive films were obtained in the same manner as that in Example 1 except the above.

As Comparative Example 4, a transparent conductive film was obtained by performing adsorption treatment in which the dispersion film of the silver nanowires of Comparative Example 1 was immersed in the above-described treatment solution of Isolan Black NHF-S at 80° C. for 10 minutes to allow the dye in the solution to be adsorbed to the silver nanowire in the dispersion film, without performing surface treatment to the dispersion film with 1-dodecanethiol.

The types and the treatment conditions of the thiols and the dyes used in Examples 1 to 8 and Comparative Examples 1 to 4 above are indicated in Table 1. Here, the “functional group” in the table represents a functional group contained in each dye and to be adsorbed to a metal filler.

### Reference Examples 1 to 10

In Reference Examples 1 to 10, the following dyes were used. Each of the dyes was dissolved in dimethyl sulfoxide at 0.25% by mass. In Reference Example 1, NK-8990 (Hayashibara Co., Ltd.) was used as a dye. In Reference Example 2, Red AQ-LE (Nippon Kayaku Co., Ltd.) was used as a dye. In Reference Example 3, Black TN200 (Nippon Kayaku Co., Ltd.) was used as a dye. In Reference Example 4, Blue AQ-LE (Nippon Kayaku Co., Ltd.) was used as a dye. In Reference Example 5, Black ECX300 (Nippon Kayaku Co., Ltd.) was used as a dye. In Reference Example 6, Blue 2R-SF (Nippon Kayaku Co., Ltd.) was used as a dye. In Reference Example 7, 1,1′-ferrocenedicarboxylic acid (Tokyo Chemical Industry Co., Ltd.) was used as a dye. In Reference Example 8, LF1550 (Taoka Chemical Company, Limited) was used as a dye. In Reference Example 9, LF1420 (Taoka Chemical Company, Limited) was used as a dye. In Reference Example 10, SE-RPD(A) Yellow (Sumitomo Chemical Company, Limited) was used as a dye.

In each of Reference Examples 1 to 10, a transparent conductive film was obtained by performing adsorption treatment in which the dispersion film of the silver nanowires of Comparative Example 1 was immersed in the above-described treatment solution at 80° C. for 10 minutes to allow the dye in the solution to be adsorbed to the silver nanowire in the dispersion film, without performing surface treatment to the dispersion film of the silver nanowires with thiols and/or sulfides.

### Example 9

### Initial Mixing

First, a silver nanowire was prepared as a metal nanowire. Here, a silver nanowire having a diameter of 30 nm and a length of 10 μm was prepared, by an existing method referring to a literature (“ACS Nano” 2010, VOL. 4, NO. 5, p. 2955-2963).

Next, the following materials were placed in ethanol together with the prepared silver nanowires, and the silver nanowires were dispersed in ethanol using ultrasonic waves to prepare a dispersion.

Next, the following materials were placed in ethanol together with the prepared silver nanowires, and the silver nanowires were dispersed in ethanol using ultrasonic waves to prepare a dispersion.

Silver nanowires: 0.28% by mass
6-hydroxy-1-hexanethiol (thiols, Aldrich Co.): 0.0002% by mass
Lanyl Black BG E/C (dye, Okamoto Dyestuff.): 0.002% by mass
PVP K-30 (a dispersant, Junsei Chemical.): 0.2% by mass Ethanol (a solvent): 99.5178% by mass

A transparent substrate was coated with the prepared dispersion using a No. 8 coil bar to form a dispersion film. The basis weight of the silver nanowires was set to be about 0.05 g/m². As the transparent substrate, a PET (U34, manufactured by Toray Industries, Inc.) having a thickness of 125 μm was used. Next, heating treatment was performed in the atmosphere at 80° C. for 2 minutes to dry and remove the solvent in the dispersion film. Accordingly, a transparent conductive film in which the silver nanowires to which thiols and a dye were adsorbed were integrated on the transparent substrate without being dispersed in the transparent resin material.

The types and the treatment conditions of the thiols and the dyes used in Reference Examples 1 to 10 and Example 9 above are indicated in Table 2. Here, the “functional group” in the table represents a functional group contained in each dye and adsorbed to the metal filler.

<Evaluation>

The transparent conductive films prepared in Examples 1 to 9, Comparative Examples 1 to 4, and Reference Examples 1 to 10 were evaluated for A) total light transmittance [%], B) HAZE, C) milky appearance, D) sheet resistance value [Ω/□], and E) reflection L value. Each evaluation was conducted as follows. The result of each evaluation is indicated in Table 3 and Table 4.

### <A) Evaluation of Total Light Transmittance>

Evaluation was conducted using HM-150 (trade name; manufactured by Murakami Color Research Laboratory) in accordance with JIS K7361.

### <B) Evaluation of HAZE>

Evaluation was conducted using HM-150 (trade name; manufactured by Murakami Color Research Laboratory) in accordance with JIS K7136.

### <C) Evaluation of Milky Appearance>

A portion not subjected to adsorption treatment (an untreated portion) was formed next to a portion subjected to adsorption treatment (a treated portion) in the examples except Comparative Example 1. Visual inspection was performed from the transparent substrate side in a state of bonding a black tape on a dispersion film (wire layer) side where the treated portion and the untreated portion were formed, and occurrence of milky appearance was evaluated according to three levels of A, B, and C as below. A: The boundary between the treated portion and the untreated portion can be easily determined, and milky appearance in the treated portion is reduced.

B: The boundary between the treated portion and the untreated portion is difficult to be recognized, but milky appearance in the treated part is reduced.
C: The boundary between the treated portion and the untreated portion is not recognized, and milky appearance in the treated part is present.

Here, Comparative Example 1 is equivalent to the untreated portion of the examples except Comparative Example 1. That is, the three level evaluation of the examples except Comparative Example 1 is based on Comparative Example 1.

### <D) Evaluation of Sheet Resistance Value>

Evaluation was performed by bringing a measurement probe into contact with the dispersion film (wire layer) side using EC-80P (trade name; Napson Corporation).

### <E) Evaluation of Reflection L Value>

The reflection L value was evaluated with the sample used for evaluating the milky appearance in accordance with JIS 28722 using Color i5 manufactured by X-Rite, Incorporated.

TABLE 1

| | Thiols and/or sulfides | | Dye | | | |
|---|---|---|---|---|---|---|
| | | Adsorption treatment | | | | Adsorption treatment |
| | Material | conditions | Material | Chromophore | Functional group | conditions |
| Comparative | — | — | — | — | — | — |
| Example 1 | | | | | | |
| Comparative | 6-hydroxy-1-hexanethiol | Room temperature (RT) | — | — | — | — |
| Example 2 | | for 5 min | | | | |
| Example 1 | | | Lanyl Black BG E/C | Cr complex. | Sulfo group | 80° C. 15 min |
| Example 2 | | | | Azo group | | 80° C. 20 min |
| Example 3 | | | | | | 80° C. 25 min |
| Example 4 | | | | | | 80° C. 30 min |
| Comparative | — | — | | | | RT 30 min |
| Example 3 | | | | | | |
| Example 5 | 1-dodecanethiol | RT for 5 min | Lanyl Black BG E/C | Cr complex. | Sulfo group | 80° C. 30 min |
| Example 6 | | RT for 1 min | | Azo group | | |
| Example 7 | 1-dodecanethiol | RT for 5 min | Isolan Black NHF-S | Cr complex. | Sulfo group | 80° C. 30 min |
| Example 8 | | | | Azo group | | 80° C. 90 min |
| Comparative | — | — | | | | 80° C. 10 min |
| Example 4 | | | | | | |

TABLE 2

| | | | Dye | | | |
|---|---|---|---|---|---|---|
| | Thiols and/or sulfides | | | | | Adsorption |
| | | Adsorption treatment | | | | treatment |
| | Material | conditions | Material | Chromophore | Functional group | conditions |
| Reference | — | — | NK-8990 | Cyanine | Carboxyl group | 80° C. 10 min |
| Example 1 | | | | | | |
| Reference | — | — | Red AQ-LE | Quinone | Sulfo group | 80° C. 10 min |
| Example 2 | | | | | | |
| Reference | — | — | Black TN200 | Quinone | Sulfo group | 80° C. 10 min |
| Example 3 | | | | | | |
| Reference | — | — | Blue AQ-LE | Quinone | Sulfo group | 80° C. 10 min |
| Example 4 | | | | | | |
| Reference | — | — | Black ECX300 | Quinone | Amino group | 80° C. 10 min |
| Example 5 | | | | | | |
| Reference | — | — | Blue 2R-SF | Quinone | Amino group | 80° C. 10 min |
| Example 6 | | | | | | |
| Reference | — | — | 1,1′- | Ferrocene | Carboxyl group | 80° C. 10 min |
| Example 7 | | | ferrocenedicarboxylic | | | |
| | | | acid | | | |
| Reference | — | — | LF 1550 | Triphenylmethane | Carboxyl group | 80° C. 10 min |
| Example 8 | | | | | | |
| Reference | — | — | LF 1420 | Triphenylmethane | Carboxyl group | 80° C. 10 min |
| Example 9 | | | | | | |
| Reference | — | — | SE-RPD (A) Yellow | Quinoline | Carboxyl group | 80° C. 10 min |
| Example 10 | | | | | | |
| Example 9 | 6-hydroxy-1-hexanethiol | Initial mixing | Lanyl Black BG E/C | Cr complex, Azo group | Sulfo group | Initial mixing |

TABLE 3

| | Total light | | | Sheet | |
|---|---|---|---|---|---|
| | transmittance | HAZE | Milky | resistance | Reflect- |
| | (%) | (%) | appearance | [Ω/□] | ance L |
| Comparative | 90.4 | 0.9 | — | 110 | 9.5 |
| Example 1 | | | | | |
| Comparative | 90.4 | 0.9 | C | 126 | 9.4 |
| Example 2 | | | | | |
| Example 1 | 90.5 | 0.7 | A | 139 | 8.1 |
| Example 2 | 90.5 | 0.6 | A | 171 | 7.6 |
| Example 3 | 90.6 | 0.6 | A | 237 | 7.1 |
| Example 4 | 90.8 | 0.5 | A | 599 | 6.8 |
| Comparative | 90.7 | 0.6 | A | OVER | 7 |
| Example 3 | | | | RANGE | |
| Example 5 | 90.6 | 0.6 | A | 149 | 7.8 |
| Example 6 | 90.6 | 0.6 | A | 348 | 7.5 |
| Example 7 | 90.4 | 0.8 | B | 112 | 8.6 |
| Example 8 | 90.5 | 0.8 | A | 124 | 8.1 |
| Comparative | 90.5 | 0.8 | A | 291 | 8.5 |
| Example 4 | | | | | |

TABLE 4

| | Total light | | | Sheet | |
|---|---|---|---|---|---|
| | transmittance | HAZE | Milky | resistance | Reflect- |
| | (%) | (%) | appearance | [Ω/□] | ance L |
| Reference | 90.5 | 0.8 | B | 319 | 8.8 |
| Example 1 | | | | | |
| Reference | 90.4 | 0.8 | B | 118 | 9.1 |
| Example 2 | | | | | |
| Reference | 90.5 | 0.8 | B | 223 | 8.6 |
| Example 3 | | | | | |
| Reference | 90.5 | 0.8 | B | 157 | 8.7 |
| Example 4 | | | | | |
| Reference | 90.5 | 0.7 | A | 330 | 8.4 |
| Example 5 | | | | | |
| Reference | 90.6 | 0.7 | A | 310 | 8.4 |
| Example 6 | | | | | |
| Reference | 90.5 | 0.8 | B | 185 | 8.8 |
| Example 7 | | | | | |
| Reference | 90.5 | 0.8 | B | 131 | 9 |
| Example 8 | | | | | |
| Reference | 90.4 | 0.8 | B | 152 | 9.1 |
| Example 9 | | | | | |
| Reference | 90.5 | 0.8 | B | 148 | 9.1 |
| Example 10 | | | | | |
| Example 9 | 90.5 | 0.6 | A | 150 | 7.9 |

The results of Examples 1 to 4 and Comparative Examples 1 to 3 confirmed the effect that 6-hydroxy-1-hexanethiol suppresses the increase in the sheet resistance caused by the addition of the dye. Furthermore, the results of Examples 5 and 6 indicated that 1-dodecanethiol also had the effect of suppressing the increase in the sheet resistance. Also, it was confirmed that the longer adsorption treatment time with 1-dodecanethiol increases the effect of suppressing the increase in the sheet resistance. The results of Examples 7 and 8 and Comparative Example 4 confirmed that 1-dodecanethiol also had the effect of suppressing the increase in the sheet resistance for the dye Isolan Black NHF-S. The result of Example 9 confirmed that 6-hydroxy-1-hexanethiol also had the effect of suppressing the increase in the sheet resistance by the method of initial mixing.

### (Consideration)

It is inferred that the phenomenon in which the resistance in the transparent conductive film is increased by the surface treatment with a dye (a colored compound) is implicated in the fact that a complex is formed between metal and a dye when the dye is adsorbed to the surface of the metal nanowire in some combinations of the dye and the metal.

### Example 10

Using a photosensitive resin as a resin material, a transparent conductive element including a patterned transparent conductive film was manufactured as below.

First, a silver nanowire [1] having a diameter of 30 nm and a length of 10 μm was produced in the same manner as that in Example 1.

Next, a dispersion of the silver nanowires [1] was prepared using the prepared silver nanowires [1] and the materials below. Silver nanowires [1]: 0.11% by mass

Photosensitive group azide-containing polymer manufactured by Toyo Gosei Co., Ltd. (average weight molecular weight 100,000): 0.272% by mass

Colored compound (Lanyl Black BG E/C manufactured by Okamoto Dyestuff.): 0.0027% by mass

Thiol compound (2-amino ethanethiol manufactured by Tokyo Chemical Industry Co., Ltd.): 0.0003% by mass

Water: 89.615% by mass

Ethanol: 10% by mass

A top of a transparent substrate was coated with the prepared dispersion using a No. 8 coil bar to form a dispersion film. The basis weight of the silver nanowires was set to be about 0.02 g/m². As the transparent substrate, a PET (Lumirror@U34 manufactured by Toray Industries, Inc.) having a thickness of 100 μm was used.

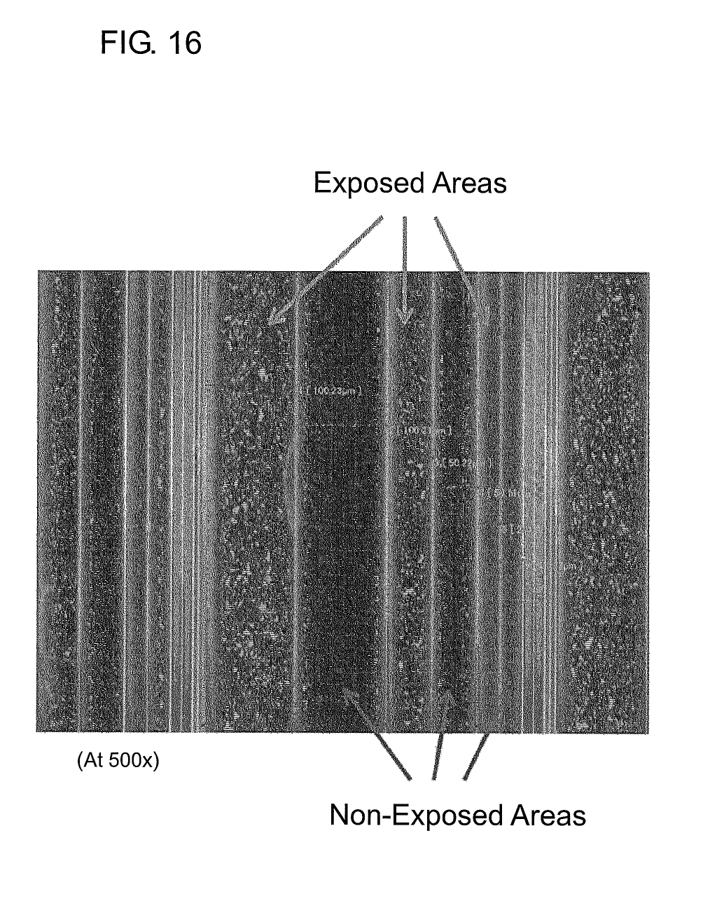

Next, heating treatment was performed in the atmosphere at 80° C. for 3 minutes to dry and remove the solvent in the dispersion film. A photo mask (see FIG. 16) was brought into soft contact with the coat, and irradiated with ultraviolet rays having an integrated light quantity of 10 mJ using an alignment exposure device manufactured by Toshiba Lighting & Technology Corporation to cure the exposed portion.

Next, spraying was performed in a shower-like manner with 100 mL of a 20% by mass aqueous solution of acetic acid to remove the unexposed portion, whereby development was performed. Thereafter, calendering treatment (nip width 1 mm, load 4 kN, speed 1 m/min) was performed.

### Examples 11 and 12

Instead of Lanyl Black BG E/C manufactured by Okamoto Dyestuff., DEN manufactured by Shinko Corporation (Example 11) or LA1920 manufactured by Taoka Chemical Company, Limited (Example 12) was used as a colored compound to manufacture a transparent conductive element by the procedure of Example 10.

### Examples 13 and 14

A transparent conductive element was manufactured by the procedure of Example 10, except that the integrated light quantity during irradiation was changed to 1 mJ or 5000 mJ.

### Example 15

A transparent conductive element was manufactured by the same procedure as that in Example 10, by using a photosensitive group azido-containing polymer (average weight molecular weight 25,000) manufactured by Toyo Gosei Co., Ltd. instead of a photosensitive group azide-containing polymer manufactured by Toyo Gosei Co., Ltd. (average weight molecular weight 100,000) used in Example 10.

### Example 16

A dispersion of silver nanowires was prepared using the silver nanowires [1] similar to Example 1 and the materials below. Silver nanowires [1]: 0.11% by mass

Functional oligomer (CN9006 manufactured by Sartomer): 0.176% by mass

Pentaerythritol triacrylate (triester 37%) (A-TMM-3 manufactured by Shin Nakamura Chemical Co., Ltd.): 0.088% by mass

Polymerization initiator (Irgacure 184 manufactured by BASF): 0.008% by mass

Colored compound (Lanyl Black BG E/C manufactured by Okamoto Dyestuff.): 0.0027% by mass

Thiol compound (2-amino ethanethiol manufactured by Tokyo Chemical Industry Co., Ltd.): 0.0003% by mass

IPA: 96.615% by mass

DAA: 3% by mass

Using the prepared dispersion, a transparent conductive element was produced in the same manner as that in Example 10. However, the integrated light quantity of ultraviolet irradiation was set at 800 mJ, and IPA was used as a developer solution instead of 20 wt % aqueous solution of acetic acid.

### Comparative Example 5

A dispersion of silver nanowires was prepared using the silver nanowires [1] similar to Example 1 and the materials below. This dispersion does not contain any colored compound.

Silver nanowires [1]: 0.11% by mass Photosensitive group azide-containing polymer manufactured by Toyo Gosei Co., Ltd. (average weight molecular weight 100,000): 0.272% by mass

Water: 89.618% by mass

Ethanol: 10% by mass

Using the prepared dispersion, a transparent conductive element was produced in the same manner as that in Example 10.

### <Evaluation>

The transparent conductive elements obtained in Examples 11 to 17 and Comparative Example 5 were evaluated for (A) total light transmittance [%], (B) haze value, (C) sheet resistance value [Ω/□], (D) reflection L value, (E) adhesion, (F) resolution, and (G) invisibility as below. The results thereof are indicated in Table 5.

(A) Total light transmittance: similar to Example 1

(B) Haze value: similar to Example 1

(C) Evaluation of sheet resistance value MCP-T360 (trade name; manufactured by Mitsubishi Chemical Analytech.) was used for evaluation.

(D) Reflection L value: similar to Example 1

(E) Adhesion

Evaluation was performed in accordance with JIS K5400 by a cross-cut (1 mm interval×100 squares) cellophane tape (CT24 manufactured by Nichiban Co., Ltd.) peeling test.

(F) Resolution

Evaluation was performed using VHX-1000 manufactured by Keyence under dark field at a magnification of 100 to 1000 according to the evaluation criteria below.

Evaluation Criteria of Resolution

AA: When the error range of the 25 μm line width of the electrode pattern is within ±10% compared to the photo mask set value in all of five points randomly selected within the coat plane

A: When the above error range is within ±20%

B: When the above error range exceeds ±20%

(G) Invisibility

A plane on a transparent conductive film side of a transparent conductive element was bonded onto 3.5 inch (diagonal) liquid crystal display through an adhesive sheet so as to face the screen. Next, an AR film was bonded to a substrate (a PET film) side of the transparent conductive element through an adhesive sheet. Then, the liquid crystal display was black-displayed, and the display screen was observed by visual inspection. The invisibility was evaluated according to the criteria below.

Evaluation criteria of invisibility

AA: Patterns are not visually recognized at all from any angle.

A: Patterns are very difficult to be visually recognized, but can be visually recognized from some angles.

C: Visually recognizable.

TABLE 5

| | | (A) Total light | (B) Haze value | (C) Sheet | (D) Reflectance L | (E) | (F) | (G) |
|---|---|---|---|---|---|---|---|---|
| | Colored compound | transmittance (%) | (%) | resistance (Ω/□) | value | Adhesion | Resolution | Invisibility |
| Example 10 | Lanyl Black BG E/C | 91.2 | 0.9 | 100 | 8 | 100/100 | AA | AA |
| Example 11 | DEN | 90.8 | 1 | 100 | 8.7 | 100/100 | AA | A |
| Example 12 | LA 1920 | 90.9 | 1 | 100 | 8.4 | 100/100 | AA | AA |
| Example 13 | Lanyl Black BG E/C | 91.2 | 0.9 | 100 | 8.1 | 100/100 | AA | AA |
| Example 14 | Lanyl Black BG E/C | 91 | 0.9 | 100 | 8.1 | 100/100 | A | AA |
| Example 15 | Lanyl Black BG E/C | 91.3 | 0.9 | 100 | 8.1 | 100/100 | AA | AA |
| Example 16 | Lanyl Black BG E/C | 90.6 | 1 | 100 | 8.2 | 100/100 | A | AA |
| Comparative | None | 90.4 | 1 | 100 | 8.8 | 100/100 | AA | C |
| Example 5 | | | | | | | | |

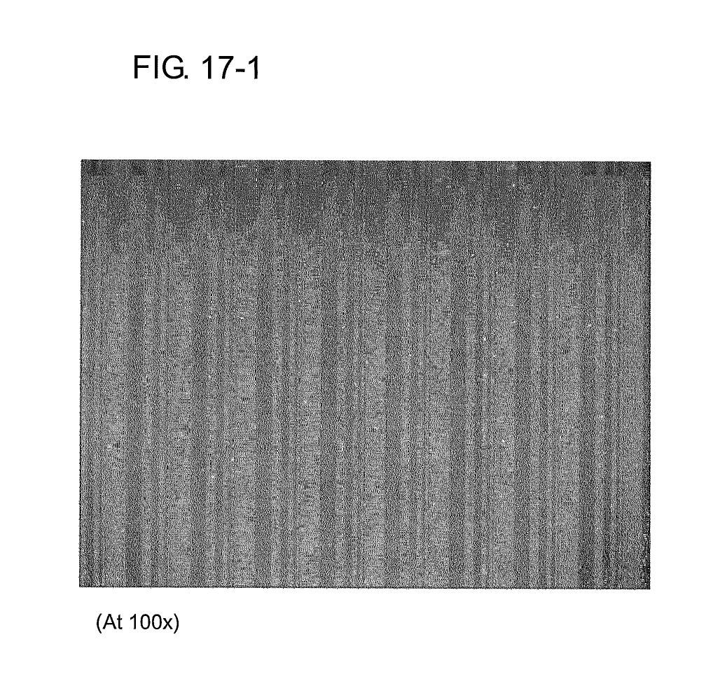

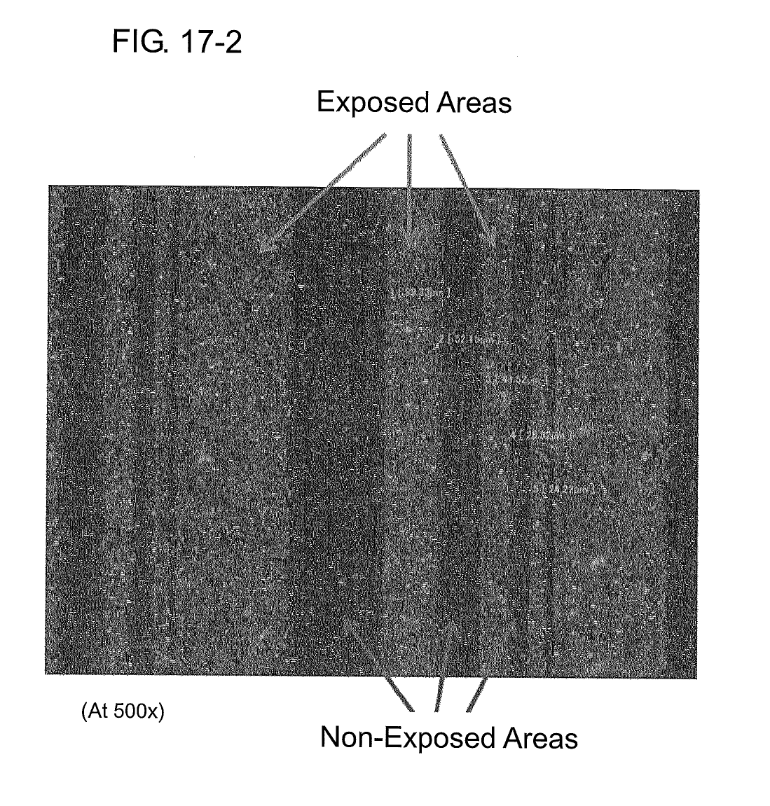

As seen from Table 5, the development property of each of Examples 10 to 16 was favorable, and the invisibility was also favorable. As a representative example, optical micrograph images of Example 10 are shown in FIG. 17-1 and FIG. 17-2. As shown in FIG. 17-1 and FIG. 17-2, in Example 10, the actually measured value of the electrode pattern having a line width of 25 μm falls within an error range of ±10%. The resolution of each of Examples 14 and 16 is lower than that of each of Examples 10 to 13 and 15. It is considered that this is because in Example 14, some light leaked to the unexposed portion during irradiation of light having an integrated light quantity of 5000 mJ, or propagation of the reaction occurred; and in Example 16, the reaction propagated to the unexposed portion.

Although the embodiments and Examples of the present technique have been specifically described above, the present technique is not limited to the above embodiments and Examples, and various modifications based on the technical idea of the present technique can be made.

For example, the configurations, the methods, the steps, the shapes, the materials, the numerical values, and the like in the above embodiments and Examples are illustrative only, and different configurations, methods, steps, shapes, materials, numerical values, and the like can be used as needed.

Furthermore, the configurations, the methods, the steps, the shapes, the materials, the numerical values, and the like in the above embodiments and Examples can be combined to each other without departing from the spirit of the present technique. For example, two or more of the first to seventh modifications in the first embodiment can be used in combination.

Although the configuration where the transparent conductive film is provided on the surface of the substrate is illustrated in the above embodiments and Examples, the transparent conductive film may be used singly without the substrate.

### REFERENCE SIGNS LIST

1, 1₁, 1₂ transparent conductive element
11 substrate
12 transparent conductive film
21 metal filler
22 resin material
23 colored compound
24 surface protective agent
25 dispersant
31 overcoat layer
32 anchor layer
33, 34 hard coat layer
35, 36 anti-reflection layer

1. A transparent conductive film comprising:
a metal filler;
a colored compound provided on a surface of the metal filler; and
at least one of thiols, sulfides, and disulfides provided on the surface of the metal filler.

2. The transparent conductive film according to claim 1, wherein the colored compound is adsorbed to the surface of the metal filler, and at least one of thiols, sulfides, and disulfides is adsorbed to the surface of the metal filler.

3. The transparent conductive film according to claim 1, wherein, when a terminal on a metal filler side of the colored compound is not any of thiols, sulfides, and disulfides, at least one of colorless thiols, sulfides, and disulfides is adsorbed to the surface of the metal filler.

4. The transparent conductive film according to claim 1, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

5. The transparent conductive film according to claim 1, wherein the colored compound absorbs light in a visible light range.

6. The transparent conductive film according to claim 5, wherein the colored compound is a dye.

7. The transparent conductive film according to claim 1, wherein the colored compound has a chromophore absorbing light in a visible light range, and a functional group being adsorbed to the metal filler.

8. The transparent conductive film according to claim 1, wherein the colored compound is represented by the following general formula (1),
R-X (1)
wherein R is a chromophore absorbing light in a visible light range, and X is a group being adsorbed to the metal filler.

9. The transparent conductive film according to claim 8, wherein the chromophore has at least one chemical structure of a chromosphore of cyanine, quinone, ferrocene, triphenylmethane, or quinoline.

10. The transparent conductive film according to claim 3, wherein the group being adsorbed to the metal filler in the colored compound is a carboxylic acid group, a phosphate group, a sulfo group, or a hydroxyl group.

11. The transparent conductive film according to claim 1, wherein the metal filler is a metal nanowire.

12. The transparent conductive film according to claim 1, wherein the metal filler contains at least one selected from Ag, Au, Ni, Cu, Pd, Pt, Rh, Ir, Ru, Os, Fe, Co, and Sn.

13. The transparent conductive film according to claim 1, wherein a reflection L value is 8 or lower.

14. The transparent conductive film according to claim 1, further comprising a resin material.

15. The transparent conductive film according to claim 1, further comprising a dispersant provided on the surface of the metallic filler.

16. The transparent conductive film according to claim 15, wherein the surfactant is adsorbed to the surface of the metal filler.

17. A composition comprising:
a metal filler;
a colored compound provided on a surface of the metal filler; and
at least one of thiols, sulfides, and disulfides provided on the surface of the metal filler.

18. The composition according to claim 17, wherein the colored compound is adsorbed to the surface of the metal filler, and at least one of thiols, sulfides, and disulfides is adsorbed to the surface of the metal filler.

19. The composition according to claim 17, wherein, when a terminal on a metal filler side of the colored compound is not any of thiols, sulfides, and disulfides, at least one of colorless thiols, sulfides, and disulfides is adsorbed to the surface of the metal filler.

20. The composition according to claim 17, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

21. The composition according to claim 17, wherein the colored compound absorbs light in a visible light range.

22. A conductive element comprising:
a substrate; and
a transparent conductive film provided on a surface of the substrate,
wherein the transparent conductive film includes:
a metal filler;
a colored compound provided on a surface of the metal filler; and
at least one of thiols, sulfides, and disulfides provided on the surface of the metal filler.

23. The conductive element according to claim 22, wherein the colored compound is adsorbed to the surface of the metal filler, and at least one of thiols, sulfides, and disulfides is adsorbed to the surface of the metal filler.

24. The conductive element according to claim 22, wherein, when a terminal on a metal filler side of the colored compound is not any of thiols, sulfides, and disulfides, at least one of colorless thiols, sulfides, and disulfides is adsorbed to the surface of the metal filler.

25. The transparent conductive film according to claim 22, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

26. An input device comprising:
a substrate; and
a transparent conductive film provided on a surface of the substrate,
wherein the transparent conductive film includes:
a metal filler;
a colored compound provided on the surface of the metal filler; and
at least one of thiols, sulfides, and disulfides provided on the surface of the metal filler.

27. The input device according to claim 26, wherein the colored compound is adsorbed to the surface of the metal filler, and at least one of thiols, sulfides, and disulfides is adsorbed to the surface of the metal filler.

28. The input device according to claim 26, wherein, when a terminal on a metal filler side of the colored compound is not any of thiols, sulfides, and disulfides, at least one of colorless thiols, sulfides, and disulfides is adsorbed to the surface of the metal filler.

29. The input device according to claim 26, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

30. An input device comprising:
a first substrate, and a first transparent conductive film provided on a surface of the first substrate; and
a second substrate, and a second transparent conductive film provided on a surface of the second substrate,
wherein the first transparent conductive film and the second transparent conductive film each include:
a metal filler;
a colored compound provided on a surface of the metal filler; and
at least one of thiols, sulfides, and disulfides provided on the surface of the metal filler.

31. The input device according to claim 30, wherein the colored compound is adsorbed to the surface of the metal filler, and at least one of thiols, sulfides, and disulfides is adsorbed to the surface of the metal filler.

32. The input device according to claim 30, wherein, when a terminal on a metal filler side of the colored compound is not any of thiols, sulfides, and disulfides, at least one of colorless thiols, sulfides, and disulfides is adsorbed to the surface of the metal filler.

33. The input device according to claim 30, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

34. An input device comprising:
a substrate having a first surface and a second surface;
a first transparent conductive film provided on the first surface; and
a second transparent conductive film provided on the second surface,
wherein the first transparent conductive film and the second transparent conductive film each include:
a metal filler;
a colored compound provided on a surface of the metal filler; and
at least one of thiols, sulfides, and disulfides provided on the surface of the metal filler.

35. The input device according to claim 34, wherein the colored compound is adsorbed to the surface of the metal filler, and at least one of thiols, sulfides, and disulfides is adsorbed to the surface of the metal filler.

36. The input device according to claim 34, wherein, when a terminal on a metal filler side of the colored compound is not any of thiols, sulfides, and disulfides, at least one of colorless thiols, sulfides, and disulfides is adsorbed to the surface of the metal filler.

37. The input device according to claim 34, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

38. A display device comprising
a display unit, and an input device provided in the display unit or on a surface of the display unit,
wherein the input device includes a substrate, and a transparent conductive film provided on a surface of the substrate,
wherein the transparent conductive film includes:
a metal filler;
a colored compound provided on a surface of the metal filler; and
at least one of thiols, sulfides, and disulfides provided on the surface of the metal filler.

39. The display device according to claim 38, wherein the colored compound is adsorbed to the surface of the metal filler, and at least one of thiols, sulfides, and disulfides is adsorbed to the surface of the metal filler.

40. The display device according to claim 39, wherein, when a terminal on a metal filler side of the colored compound is not any of thiols, sulfides, and disulfides, at least one of colorless thiols, sulfides, and disulfides is adsorbed to the surface of the metal filler.

41. The display device according to claim 38, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.

42. An electronic instrument comprising
a display unit, and an input device provided in the display unit or on a surface of the display unit,
wherein the input device includes a substrate, and a transparent conductive film provided on a surface of the substrate,
wherein the transparent conductive film includes:
a metal filler;
a colored compound provided on a surface of the metal filler; and
at least one of thiols, sulfides, and disulfides provided on the surface of the metal filler.

43. The electronic instrument according to claim 42, wherein the colored compound is adsorbed to the surface of the metal filler, and at least one of thiols, sulfides, and disulfides is adsorbed to the surface of the metal filler.

44. The electronic instrument according to claim 42, wherein, when a terminal on a metal filler side of the colored compound is not any of thiols, sulfides, and disulfides, at least one of colorless thiols, sulfides, and disulfides is adsorbed to the surface of the metal filler.

45. The electronic instrument according to claim 42, wherein, when a terminal on a metal filler side of the colored compound is thiols, sulfides, or disulfides, the colored compound provided on the surface of the metal filler and the thiols, sulfides, or disulfides provided on the surface of the metal filler are shared with each other.
